(19) United States
(12) Patent Application Publication
(10) Pub. No.: US 2024/0237517 A1
(43) Pub. Date: Jul. 11, 2024

(54) ORGANIC LIGHT EMITTING DIODE AND ORGANIC LIGHT EMITTING DEVICE

(71) Applicant: LG Display Co., Ltd., Seoul (KR)

(72) Inventors: Yu-Jeong LEE, Paju-si (KR); Sang-Beom KIM, Paju-si (KR); Eun-Jung PARK, Paju-si (KR); Ju-Hyuk KWON, Paju-si (KR); Jang-Dae YOUN, Paju-si (KR); Shin-Young JEONG, Paju-si (KR); Hyun-Jin CHO, Paju-si (KR); Jun-Su HA, Paju-si (KR)

(73) Assignee: LG Display Co., Ltd., Seoul (KR)

(21) Appl. No.: 18/242,851

(22) Filed: Sep. 6, 2023

(30) Foreign Application Priority Data
Dec. 26, 2022 (KR) 10-2022-0184110

(51) Int. Cl. H10K 85/60; H10K 50/13

(52) U.S. Cl. CPC H10K 85/654; H10K 50/13; H10K 85/615; H10K 85/626; H10K 85/6572; H10K 50/166

(57) ABSTRACT

An organic light emitting diode (OLED) is described, having an emissive layer with an emitting part including at least one emitting material layer, a first electron transport layer, and a second electron transport layer disposed sequentially between two facing electrodes. The first electron transport layer includes a first electron transporting material of an azine-containing compound and the second electron transport layer includes a second electron transporting material of a benzimidazole-containing compound. The first electron transport layer, with controlled electron transporting property and energy level, is disposed adjacently to the at least one emitting material layer and the second electron transporting layer is disposed adjacently to the second electrode or an electron injection layer so that the OLED can lower driving voltage and can maximize luminous efficiency and luminous lifespan. An organic light emitting device including the OLED can be a display device or a lighting device.

### CROSS-REFERENCE TO RELATED APPLICATIONS

This application claims priority, under 35 U.S.C. § 119(a), to Korean Patent Application No. 10-2022-0184110, filed in the Republic of Korea on Dec. 26, 2022, which is expressly incorporated by reference in its entirety into the present application.

### BACKGROUND

### Technical Field

The present disclosure relates to an organic light emitting diode (OLED), preferably an OLED with improved luminous efficiency and luminous lifespan, as well as an organic light emitting device (e.g., a display device or a lighting device) including the OLED.

### Discussion of the Related Art

Flat panel display devices including an organic light emitting diode (OLED) have certain advantages over a liquid crystal display device (LCD). For instance, the OLED can be formed as a thin organic film less than 2000 Å, and the electrode configurations can implement unidirectional or bidirectional images. Also, the OLED can be formed on a flexible transparent substrate such as a plastic substrate so that a flexible or a foldable display device can easily be manufactured using the OLED. In addition, the OLED can be driven at a lower voltage and the OLED has higher color purity compared to the LCD.

However, there remains a need to develop OLEDs and devices thereof that have improved luminous efficiency and luminous lifespan. Since fluorescent materials use only singlet excitons in the luminous process, there is an issue with low luminous efficiency. Meanwhile, phosphorescent materials can show high luminous efficiency since they use triplet exciton as well as singlet excitons in the luminous process. But, examples of such phosphorescent material include metal complexes, which can have a short luminous lifespan, which can be too short for commercial use. As such, there remains a need to develop an OLED with sufficient luminous efficiency, luminous lifespan and color purity.

### SUMMARY OF THE DISCLOSURE

Embodiments of the present disclosure are directed to an organic light emitting diode and an organic light emitting device that address one or more of the limitations and disadvantages of the related art. An organic light-emitting diode and device thereof according to aspects of the present disclosure can operate at a low voltage, consume less power, render excellent colors, and/or can be used in a variety of applications. In an aspect, the OLED can also be formed on a flexible substrate, to provide a flexible or a foldable device. Further, the size of the OLED can be easily adjustable.

An aspect of the present disclosure is to provide an OLED with lower driving voltage to achieve lower power consumption and improved luminous efficiency and luminous lifespan, as well as an organic light emitting device including the diode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides an organic light emitting diode that comprises a first electrode; a second electrode; and an emissive layer disposed between the first electrode and the second electrode, and comprising at least one emitting part, wherein one emitting part disposed adjacently to the second electrode among the at least one emitting part comprises at least one emitting material layer; and an electron transport layer disposed between the at least one emitting material layer and the second electrode, wherein the electron transport layer comprises a first electron transport layer disposed between the at least one emitting material layer and the second electrode; and a second electron transport layer disposed between the first electron transport layer and the second electrode, wherein the first electron transport layer comprises a first electron transporting material having the following structure of Chemical Formula 1, and wherein the second electron transport layer comprises a second electron transporting material having the following structure of Chemical Formula 4:

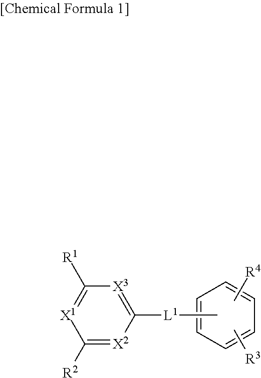

wherein, in Chemical Formula 1,
each of X¹ to X³ is independently CR⁵ or N, where at least two of X¹ to X³ is N;
each of R¹ to R⁵ is independently hydrogen, an unsubstituted or substituted C₁-C₂₀ alkyl group or an unsubstituted or substituted C₆-C₃₀ aryl group or an unsubstituted or substituted C₃-C₃₀ hetero aryl group, where at least one of R³ and R⁴ has an unsubstituted or substituted carbazolyl moiety; and
L¹ is a single bond, an unsubstituted or substituted C₆-C₃₀ arylene group or an unsubstituted or substituted C₃-C₃₀ hetero arylene group,

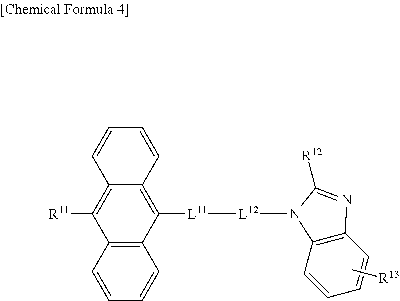

wherein, in Chemical Formula 4,
each of R¹¹ to R¹³ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
each of L¹¹ and L¹² is independently a single bond, an unsubstituted or substituted C₆-C₃₀ arylene group or an unsubstituted or substituted C₃-C₃₀ hetero arylene group, where at least one of L¹¹ and L¹² is not a single bond.

In one embodiment, the first electron transporting material can have a structure of Chemical Formula 2:

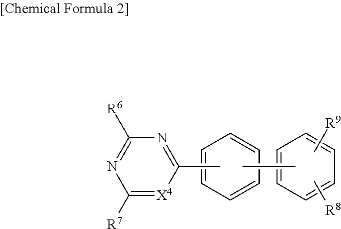

wherein, in Chemical Formula 2,
X⁴ is CR¹⁰ or N;
each of R⁶ and R⁷ is independently an unsubstituted or substituted C₆-C₃₀ aryl group;
each of R⁸ and R⁹ is independently an unsubstituted or substituted C₆-C₃₀ aryl group or an unsubstituted or substituted C₃-C₃₀ hetero aryl group, where at least one of R⁸ and R⁹ includes an unsubstituted or substituted carbazolyl moiety; and

R¹⁰ is hydrogen or an unsubstituted or substituted C₁-C₂₀ alkyl group.

In another embodiment, the second electron transporting material can have a structure of Chemical Formula 5:

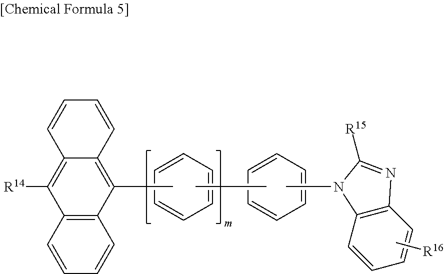

wherein, in Chemical Formula 5,
R¹⁴ is an unsubstituted or substituted C₆-C₃₀ aryl group;
R¹⁵ is hydrogen, an unsubstituted or substituted C₁-C₂₀ alkyl group or an unsubstituted or substituted C₆-C₃₀ aryl group;
R¹⁶ is hydrogen or an unsubstituted or substituted C₁-C₂₀ alkyl group; and
m is 0 or 1.

Certain embodiments relate to an organic light emitting diode comprising: a first electrode; a second electrode; and an emissive layer disposed between the first electrode and the second electrode, and comprising at least one emitting part, wherein one of the at least one emitting part is disposed adjacently to the second electrode and comprises: at least one emitting material layer; and an electron transport layer disposed between the at least one emitting material layer and the second electrode. The electron transport layer comprises: a first electron transport layer disposed between the at least one emitting material layer and the second electrode; and a second electron transport layer disposed between the first electron transport layer and the second electrode, wherein the first electron transport layer comprises a first electron transporting material having a structure of Chemical Formula 2, as described herein, and wherein the second electron transport layer comprises a second electron transporting material having a structure of Chemical Formula 5, as described herein. In an aspect, the first electron transporting material is at least one of the organic compounds 1-1 to 1-4, as described herein, and the second electron transporting material is at least one of the compounds 2-1 to 2-5, as described herein.

In one embodiment, the first electron transport layer can have a thickness different from a thickness of the second electron transport layer. In another embodiment, the first electron transport layer can have the same thickness as the second electron transport layer. For example, a thickness ratio of the first electron transport layer to the second electron transport layer can be 1:1 to 1:10, e.g., 1:1.1, 1:1.2, 1:1.3, 1:1.5, 1:2, 1:3, 1:4, 1:5, 1:7, 1:8, or 1:9. Or, a thickness ratio of the first electron transport layer to the second electron transport layer can be 1:1 to 10:1, e.g., 1.1:1, 1.2:1, 1.3:1, 1.5:1, 2:1, 3:1, 4:1, 5:1, 7:1, 8:1, or 9:1.

In one embodiment, the emissive layer can have a single emitting part.

The at least one emitting material layer can emit at least one of a red color light, a green color light, a blue color light and a yellow-green color light.

In another embodiment, the emissive layer can comprise a first emitting part disposed between the first electrode and the second electrode; a second emitting part disposed between the first emitting part and the second electrode; and a charge generation layer disposed between the first emitting part and the second emitting part, and the second emitting part can comprise the at least one emitting material layer and the electron transport layer.

The at least one emitting material layer in the second emitting part can comprise a first layer disposed between the charge generation layer and the second electrode; and a second layer disposed between the first layer and the second electrode, and optionally, a third layer disposed between the first layer and the second layer.

In another embodiment, the emissive layer can comprise a first emitting part disposed between the first electrode and the second electrode; a second emitting part disposed between the first emitting part and the second electrode; a third emitting part disposed between the second emitting part and the second electrode; a first charge generation layer disposed between the first emitting part and the second emitting part; and a second charge generation layer disposed between the second emitting part and the third emitting part, and the third emitting part can comprise the at least one emitting material layer and the electron transport layer.

In another aspect, the present disclosure provides an organic light emitting diode that comprises a first electrode; a second electrode facing the first electrode; and an emissive layer disposed between the first electrode and the second electrode, and comprising at least one emitting part, wherein one emitting part disposed adjacently to the second electrode among the at least one emitting part comprises a blue emitting material layer; and an electron transport layer disposed between the blue emitting material layer and the second electrode, wherein the electron transport layer comprises a first electron transport layer disposed between the blue emitting material layer and the second electrode; and a second electron transport layer disposed between the first electron transport layer and the second electrode, the first electron transport layer can comprises a first electron transporting material having the structure of Chemical Formula 1, and the second electron transport layer can comprise a second electron transporting material having the structure of Chemical Formula 4.

In one embodiment, the emissive layer can have a single emitting part.

In another embodiment, the emissive layer can comprise a first emitting part disposed between the first electrode and the second electrode; a second emitting part disposed between the first emitting part and the second electrode; a third emitting part disposed between the second emitting part and the second electrode; a first charge generation layer disposed between the first emitting part and the second emitting part; and a second charge generation layer disposed between the second emitting part and the third emitting part, and the third emitting part can comprise the blue emitting material layer and the electron transport layer.

The second emitting part can comprise at least one emitting material layer, the at least one emitting material layer can comprise a first layer disposed between the first charge generation layer and the second electrode; and a second layer disposed between the first layer and the second electrode, and one of the first layer and the second layer can be a red emitting material layer and another of the first layer and the second layer can be a green emitting material layer.

Alternatively, or additionally, the at least one emitting material layer can further comprise a third layer of a yellow-green emitting material layer disposed between the first layer and the second layer.

In yet another aspect, the present disclosure provides an organic light emitting device, for example, an organic light emitting display device or an organic light emitting illumination device that comprises a substrate and the organic light emitting diode over the substrate.

In one or more embodiments, the emitting part disposed adjacently to the second electrode or cathode comprises a first electron transport layer with a first electron transporting material of the azine-containing organic compound and a second electron transport layer with a second electron transporting material of the benzimidazole-containing organic compound disposed between the at least one emitting material layer and the second electrode. As used herein, the term “azine-based organic compound” comprises azine-containing organic compounds, or derivatives thereof. As used herein, the term “benzimidazole-based organic compound” comprises phenanthroline-containing organic compounds, or derivatives thereof.

The second electron transporting material has electron transporting property better than electron transporting property of the first electron transporting material. As designing the electron transporting properties of the luminous material in the emitting material layer, the first electron transporting material in the first electron transport layer and the second electron transporting material in the second electron transport layer increase gradually, holes and electrons can be injected into the emitting material layer in balance in the OLED.

The second electron transport layer comprises the second electron transporting material of the benzimidazole-containing organic compound that can combine electrons generated at the second electrode and transfer electrons efficiently. The energy levels of the emitting material layer and the electron transport layer comprising the benzimidazole-containing organic compound are controlled so as to transfer electrons efficiently to the emitting material layer from the electron transport layer.

As holes and electrons are recombined within the emitting material layer to generate excitons stably, the amount of the non-emitting quenched excitons can be minimized. The OLED and the organic light emitting device can lower driving voltage, as can maximize luminous efficiency and luminous lifespan.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with one or more embodiments of the present disclosure.

FIG. 2 illustrates a cross-sectional view of an organic light emitting display device as an example of an organic light emitting device in accordance with one or more embodiments of the present disclosure.

FIG. 3 illustrates a cross-sectional view of an organic light emitting diode having a single emitting part in accordance with one or more embodiments of the present disclosure.

FIG. 4 illustrates a cross-sectional view of an organic light emitting display device in accordance with one or more embodiments of the present disclosure.

FIG. 5 illustrates a cross-sectional view of an organic light emitting diode having a double-stack structure in accordance with one or more embodiments of the present disclosure.

FIG. 6 illustrates a cross-sectional view of an organic light emitting diode having a triple-stack structure in accordance with one or more embodiments of the present disclosure.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. In the following description, when a detailed description of well-known functions or configurations related to this document is determined to unnecessarily cloud a gist of the inventive concept, the detailed description thereof will be or can be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations are selected only for convenience of writing the specification and can be thus different from those used in actual products. Further, all the components of each organic light emitting diode (OLED) and each organic light emitting device (e.g., display device, illumination device, etc.) using the OLED according to all embodiments of the present disclosure are operatively coupled and configured.

The present disclosure relates to an organic light emitting diode and/or an organic light emitting device that includes multiple electron transport layers each of which includes electron transporting material with controlled electron transporting property and energy level disposed between at least one emitting material layer and the second electrode or an electron injection layer, so that holes and electrons can be injected into the emitting material layer in balance, the amount of the quenching excitons without emission can be minimized, and therefore, that the OLED and the device can lower driving voltages as well as maximize driving properties. The organic light emitting diode can be applied to an organic light emitting device such as an organic light emitting display device or an organic light emitting illumination device.

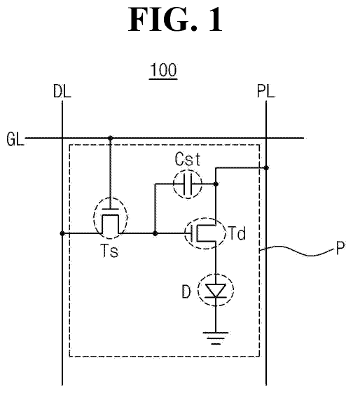

FIG. 1 illustrates a schematic circuit diagram of an organic light emitting display device in accordance with one or more embodiments of the present disclosure.

As illustrated in FIG. 1, a gate line GL, a data line DL and a power line PL, each of which crosses each other to define a pixel region P, are provided in an organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. In certain aspects, the organic light emitting display device 100 includes a plurality of such pixel regions P which can be arranged in a matrix configuration or other configurations. Further, each pixel region P can include one or more subpixels. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

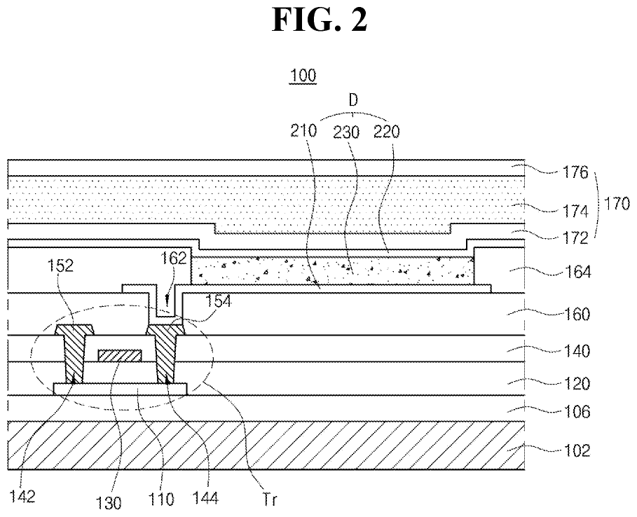

The driving thin film transistor Td is turned on by the data signal applied to a gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 includes a substrate 102, a thin-film transistor Tr on the substrate 102, and an organic light emitting diode D connected to the thin film transistor Tr. As an example, the substrate 102 can include a red pixel region, a green pixel region and a blue pixel region and an organic light emitting diode D can be located in each pixel region. Each of the organic light emitting diodes D emitting red, green and blue light, respectively, is located correspondingly in the red pixel region, the green pixel region and the blue pixel region. For example, the organic light emitting diode D can be disposed in the red pixel region, the green pixel region and the blue pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can include, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon. Here, the designation of the source and drain electrodes 152 and 154 can be switched with each other depending on the type and configuration of a transistor.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole (or a contact hole) 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed in each pixel region P. The first electrode 210 can be an anode and include conductive material having relatively high work function value. For example, the first electrode 210 can include a transparent conductive oxide (TCO). For example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer can be disposed under the first electrode 210. For example, the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. In certain embodiments, the bank layer 164 can be omitted.

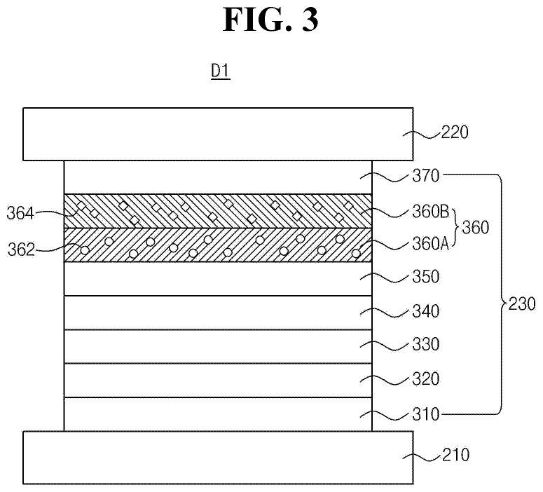

The emissive layer 230 is disposed on the first electrode 210. In one embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIGS. 3, 5 and 6).

In one embodiment, the emissive layer 230 can have a single emitting part. Alternatively, the emissive layer 230 can have multiple emitting parts to form a tandem structure.

For example, the emissive layer 230 can include a first electron transport layer disposed adjacently to the emitting material layer and a second electron transport layer disposed between the first electron transport layer and the second electrode 220, so that the intensity of light emitted from the emitting material layer can be maintained stably by improving the high temperature stability of the OLED D.

The second electrode 220 is disposed on the substrate 102 above which the emissive layer 230 is disposed. The second electrode 220 can be disposed on the entire display area. The second electrode 220 can include a conductive material with a relatively low work function value compared to the first electrode 210. The second electrode 220 can be a cathode providing electrons. For example, the second electrode 220 can include at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. In certain embodiments, the encapsulation film 170 can be omitted.

A polarizing plate or polarizer can be attached onto the encapsulation film 170 to reduce reflection of external light. For example, the polarizing plate can be a circular polarizing plate. When the organic light emitting display device 100 is a bottom-emission type, the polarizing plate can be disposed under the substrate 102. When the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window can have a flexible property, thus the organic light emitting display device 100 can be a flexible display device.

The OLED D is described in more detail. FIG. 3 illustrates a schematic cross-sectional view of an organic light emitting diode having a single emitting part in accordance with an embodiment of the present disclosure. For instance, FIG. 3 shows an example (OLED D1) of the OLED D in FIGS. 1 and 2.

As illustrated in FIG. 3, the organic light emitting diode (OLED) D1 in accordance with one embodiment includes a first electrode 210 and a second electrode 220 facing each other and an emissive layer 230 disposed between the first electrode 210 and the second electrode 220. The organic light emitting display device 100 includes a red pixel region, a green pixel region and a blue pixel region, and the OLED D1 can be disposed in the red pixel region, the green pixel region and/or the blue pixel region.

In an embodiment, the emissive layer 230 includes an emitting material layer (EML) 340 disposed between the first electrode 210 and the second electrode 220. The emissive layer 230 can include at least one of a hole transport layer (HTL) 320 disposed between the first electrode 210 and the EML 340 and an electron transport layer (ETL) 360 disposed between the second electrode 220 and the EML 340. In addition, the emissive layer 230 can further include at least one of a hole injection layer (HIL) 310 disposed between the first electrode 210 and the HTL 320 and an electron injection layer (EIL) 370 disposed between the second electrode 220 and the ETL 360. Alternatively, or additionally, the emissive layer 230 can further comprise a first exciton blocking layer, i.e. an electron blocking layer (EBL) 330 disposed between the HTL 320 and the EML 340 and/or a second exciton blocking layer, i.e. a hole blocking layer (HBL) 350 disposed between the EML 340 and the ETL 360.

The first electrode 210 can be an anode that provides a hole into the EML 340. The first electrode 210 can include a conductive material having a relatively high work function value, for example, a transparent conductive oxide (TCO). In an embodiment, the first electrode 210 can include, but is not limited to, ITO, IZO, ITZO, SnO, ZnO, ICO, AZO, and the like.

The second electrode 220 can be a cathode that provides an electron into the EML 340. The second electrode 220 can include a conductive material having a relatively low work function values, i.e., a highly reflective material such as Al, Mg, Ca, Ag, and/or alloy thereof and/or combinations thereof such as Al—Mg. For example, each of the first electrode 210 and the second electrode 220 can have, but is not limited to, a thickness of about 5 nm to about 300 nm.

The HIL 310 is disposed between the first electrode 210 and the HTL 320 and can improve an interface property between the inorganic first electrode 210 and the organic HTL 320. In one embodiment, hole injection material in the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine 1,4,5,8,9,11-Hexaazatriphenylenehexacarbonitrile (Dipyrazino[2,3-f:2′3′-(DNTPD), h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracyanonaphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), MgF₂, CaF₂ and/or combinations thereof.

In another embodiment, the HIL 310 can include a hole injecting host of hole transporting material below, and a P-type dopant of the hole injecting material. The P-type dopant can include, but is not limited to, HAT-CN, F4-TCNQ, F6-TCNNQ, NPD9 and/or combinations thereof. The contents of the P-type dopant in the HIL 310 can be, but is not limited to, about 1 wt. % to about 10 wt. %. As an example, the HIL 310 can have a thickness of, but is not limited to, about 1 nm to about 100 nm. In certain embodiments, the HIL 310 can be omitted in compliance of the OLED D1 property.

The HTL 320 is disposed between the first electrode 210 and the EML 340. In one embodiment, the hole transporting material in the HTL 320 can include, but is not limited to, N,N′-Diphenyl-N,N′-bis(3-methylphenyl)-1,1′-biphenyl-4,4′-diamine (TPD), NPB(NPD), DNTPD, N4,N4,N4′,N4′-Tetra[(1,1′-biphenyl)-4-yl]-(1,1′-biphenyl)-4,4′-diamine (BPBPA), 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof. As an example, the HTL 320 can have a thickness of, but is not limited to, about 20 nm to about 200 nm.

The EML 340 can include a host and a dopant (or an emitter). For example, the host can include a P-type host (hole-type host) and/or an N-type host (electron-type host).

In one embodiment, the EML 340 can include a blue host and a blue emitter. As an example, the blue host can include, but is not limited to, 1,3-Bis(carbazol-9-yl)benzene (mCP), 9-(3-(9H-carbazol-9-yl)phenyl)-9H-carbazole-3-carbonitrile (mCP-CN), 3,3-Di(9H-carbazol-9-yl)biphenyl (mCBP), CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), Diphenyl-4-triphenylsilyl-phenylphosphine oxide (TSPO1), 9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spiorobifluoren-2-yl-diphenyl-phosphine oxide (SPPO1), 9,9′-(5-(Triphenylsilyl)-1,3-phenylene)bis(9H-carbazole) (SimCP), 2-methyl-9,10-bis(naphthalen-2-yl)anthracene (MADN) and/or combinations thereof.

The blue emitter can include at least one of blue phosphorescent material, blue fluorescent material and blue delayed fluorescent material. As an example, the blue emitter can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1,4-di-[4-(N,N-diphenyl)amino]styryl-benzene (DSA), 2,5,8,11-Tetra-tert-butylperylene (TBPe), Bis(2-hydroxylphenyl)-pyridine)beryllium (Bepp₂), 9-(9-Phenylcarbazol-3-yl)-10-(naphthalen-1-yl)anthracene (PCAN), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), Bis(3,4,5-trifluoro-2-(2-pyridyl)phenyl-(2-carboxypyridyl)iridium(III) (Ir(tfpd)₂pic), Tris(2-(4,6-difluorophenyl)pyridine))iridium(III) (Ir(Fppy)₃), Bis[2-(4,6-difluorophenyl)pyridinato-C²,N](picolinato)iridium(III) (FIrpic), DABNA-1, DABNA-2, t-DABNA, v-DABNA and/or combinations thereof.

In another embodiment, the EML 340 can include a red host and a red emitter. The red host can include a P-type red host and/or an N-type red host. As an example, the red host can include, but is not limited to, mCP-CN, CBP, mCBP, mCP, Bis[2-(diphenylphosphino)phenyl]ether oxide (DPEPO), 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3,5′-Di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, 9,9′-Diphenyl-9H,9′H-3,3′-bicarbazole (BCzPh), 1,3,5-Tris(carbazol-9-yl)benzene (TCP), TCTA, 4,4′-Bis(carbazole-9-yl)-2,2′-dimethylbiphenyl (CDBP), 2,7-Bis(carbazole-9-yl)-9,9-dimethylfluorene (DMFL-CBP), 2,2′,7,7′-Tetrakis(carbazol-9-yl)-9,9-spirofluorene (Spiro-CBP), 3,6-Bis(carbazole-9-yl)-9-(2-ethyl-hexyl)-9H-carbazole (TCz1), BPBPA, 1,3,5-Tris(N-phenylbenzimidazol-2-yl)benzene (TPBi) and/or combinations thereof.

The red emitter can include at least one of red phosphorescent material, red fluorescent material and red delayed fluorescent material. As an example, the red dopant can include, but is not limited to, Bis[2-(4,6-dimethyl)phenylquinoline)](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(III) (Ir(Mphq)₃), Bis(2-phenylquinoline)(2,2,6,6-tetramethylheptene-3,5-dionate)iridium(III) (Ir(dpm)PQ₂), Bis(phenylisoquinoline)(2,2,6,6-tetramethylheptene-3,5-dionate)iridium(III) (Ir(dpm)(piq)₂), Bis(1-phenylisoquinoline)(acetylacetonate)iridium(III) (Ir(piq)₂(acac)), Bis[(4-n-hexylphenyl)isoquinoline](acetylacetonate)iridium(III) (Hex-Ir(piq)₂(acac)), Tris[2-(4-n-hexylphenyl)quinoline]iridium(III) (Hex-Ir(piq)₃), Tris(2-(3-methylphenyl)-7-methyl-quinolato)iridium (Ir(dmpq)₃), Bis[2-(2-methylphenyl)-7-methylquinoline](acetylacetonate)iridium(III) (Ir(dmpq)₂(acac)), Bis[2-(3,5-dimethylphenyl)-4-methylquinoline](acetylacetonate)iridium(III) (Ir(mphmq)₂(acac)), Tris(dibenzoylmethane)mono(1,10-phenanthroline)europium(III) (Eu(dbm)₃(phen)) and/or combinations thereof.

In another embodiment, the EML 340 can include a green host and a green emitter. The green host can include a P-type green host and/or an N-type green host. For example, the green host can include the blue host and/or the red host above.

The green emitter can include at least one of green phosphorescent material, green fluorescent material and green delayed fluorescent material. As an example, the green emitter can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

The contents of the host including the P-type host and the N-type host in the EML 340 can be about 50 wt. % to about 99 wt. %, for example, about 80 wt. % to about 95 wt. %, and the contents of the dopant in the EML 340 can be about 1 wt. % to about 50 wt. %, for example, about 5 wt. % to about 20 wt. %, but is not limited thereto. When the EML 340 includes both the P-type host and the N-type host, the P-type host and the N-type host can be mixed, but is not limited to, with a weight ratio of about 4:1 to about 1:4, for example about 3:1 to about 1:3. As an example, the EML 340 can have a thickness, but is not limited to, about 10 nm to about 200 nm.

The ETL 360 and the EIL 370 can be laminated sequentially between the EML 340 and the second electrode 220. An electron transporting material included in the ETL 360 has high electron mobility so as to provide electrons stably with the EML 340 by fast electron transportation.

The electron transporting material in the ETL 360 can include an azine-containing organic compound and a benzimidazole-containing organic compound that can bind electrons transferred from the second electrode 220 via the EIL 370 and that can inject rapidly electrons into the EML 340. The energy levels (e.g. LUMO energy level) between the ETL 360 including the azine-containing organic compound and the benzimidazole-containing organic compound and the EML 340 can be adjusted so as to inject electrons rapidly to the EML 340.

The ETL 360 includes a first electron transport layer (ETL1) 360A and a second electron transport layer (ETL2) 360B disposed sequentially between the EML 340 and the second electrode 220 or the EIL 370. In other words, the ETL1 360A is disposed between the EML 340 and the second electrode 220 and the ETL2 360B is disposed between the ETL1 360A and the second electrode 220.

The ETL1 360A can include a first electron transporting material (ETM1) 362 of an azine-containing organic compound with relatively low electron transporting properties. The ETM1 362 can include an azine-containing (pyrimidine-containing or triazine-containing) organic compound having the following structure of Chemical Formula 1:

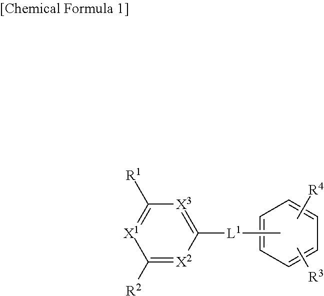

wherein, in Chemical Formula 1,
each of X¹ to X³ is independently CR⁵ or N, where at least two of X¹ to X³ is N;
each of R¹ to R⁵ is independently hydrogen, an unsubstituted or substituted C₁-C₂₀ alkyl group or an unsubstituted or substituted C₆-C₃₀ aryl group or an unsubstituted or substituted C₃-C₃₀ hetero aryl group, where at least one of R³ and R⁴ has an unsubstituted or substituted carbazolyl moiety; and
L¹ is a single bond, an unsubstituted or substituted C₆-C₃₀ arylene group or an unsubstituted or substituted C₃-C₃₀ hetero arylene group.

As used herein, the term “unsubstituted” means that hydrogen is directly linked to a carbon atom. “Hydrogen,” as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cyclo alkyl silyl group, a C₆-C₃₀ aryl silyl group, a C₃-C₃₀ hetero aryl silyl group, an unsubstituted or substituted C₆-C₃₀ aryl group, an unsubstituted or substituted C₃-C₃₀ hetero aryl group, or any combination of these groups.

As used herein, the term “hetero” in terms such as “a hetero aryl group”, and “a hetero arylene group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

The aryl group can independently include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

The hetero aryl group can independently include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

For example, each of the C₁-C₂₀ alkyl group, the C₆-C₃₀ aryl group, the C₃-C₃₀ hetero aryl group and the carbazolyl moiety of R¹ to R⁵ in Chemical Formula 1 can be independently at least one of a C₁-C₁₀ alkyl group, a C₆-C₂₀ aryl group and a C₃-C₂₀ hetero aryl group, and each of the C₆-C₃₀ arylene group and the C₃-C₃₀ hetero arylene group of L¹ in Chemical Formula 1 can be unsubstituted or substituted with at least one C₁-C₁₀ group.

In one embodiment, the unsubstituted or substituted carbazolyl moiety as at least one of R³ and R⁴ in Chemical Formula 1 can include a carbazolyl group and moieties with at least one aromatic ring and/or at least one hetero aromatic ring fused to the carbazolyl group. For example, the moiety with at least one aromatic ring and/or at least one hetero aromatic ring fused to the carbazolyl group can include, but is not limited to, an unsubstituted or substituted indeno carbazolyl group, an unsubstituted or substituted indolo carbazolyl group, an unsubstituted or substituted benzofuro carbazolyl group and an unsubstituted or substituted benzothieno carbazolyl group.

For example, each of R¹ and R² substituted to the azine ring can be independently an unsubstituted or substituted C₆-C₃₀ aryl group (e.g., phenyl and/or naphthyl), each of R³ and R⁴ can be independently an unsubstituted or substituted C₆-C₃₀ aryl group (e.g., phenyl and/or biphenyl) or an unsubstituted or substituted C₃-C₃₀ hetero aryl group (e.g., carbazolyl moiety such as carbazolyl), and/or at least one of R³ and R⁴ can be an unsubstituted or substituted carbazolyl moiety such as carbazolyl. In another embodiment, R⁵ can be hydrogen or a C₁-C₂₀ alkyl group and/or L¹ can be phenylene.

As an example, the ETM1 362 of the azine-containing organic compound can includes an organic compound having the following structure of Chemical Formula 2:

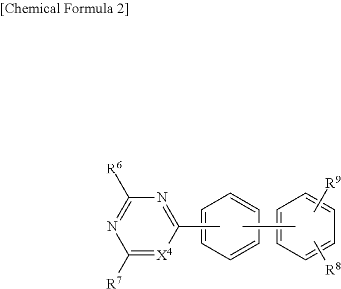

wherein, in Chemical Formula 2,
X⁴ is CR¹⁰ or N;
each of R⁶ and R⁷ is independently an unsubstituted or substituted C₆-C₃₀ aryl group;
each of R⁸ and R⁹ is independently an unsubstituted or substituted C₆-C₃₀ aryl group or an unsubstituted or substituted C₃-C₃₀ hetero aryl group, where at least one of R⁸ and R⁹ includes an unsubstituted or substituted carbazolyl moiety; and
R¹⁰ is hydrogen or an unsubstituted or substituted C₁-C₂₀ alkyl group.

In one embodiment, each of the C₁-C₂₀ alkyl group, the C₆-C₃₀ aryl group, the C₃-C₃₀ hetero aryl group and the carbazolyl moiety of R⁶ to R¹⁰ in Chemical Formula 2 can be independently unsubstituted or substituted with at least one of a C₁-C₁₀ alkyl group and a C₆-C₂₀ aryl group.

In another embodiment, the azine moiety and the right side benzene ring to which R⁸ and R⁹ can be substituted in Chemical Formula 2 can be linked to the center benzene ring at a para-position, but is not limited thereto. In another embodiment, each of R⁸ and R⁹ can be linked to the right side benzene ring at a meta-position, respectively, with respect to the linking position of the azine moiety to the center benzene ring, but is not limited thereto.

For example, the ETM1 362 can be, but is not limited to, at least one of the following organic compounds of Chemical Formula 3:

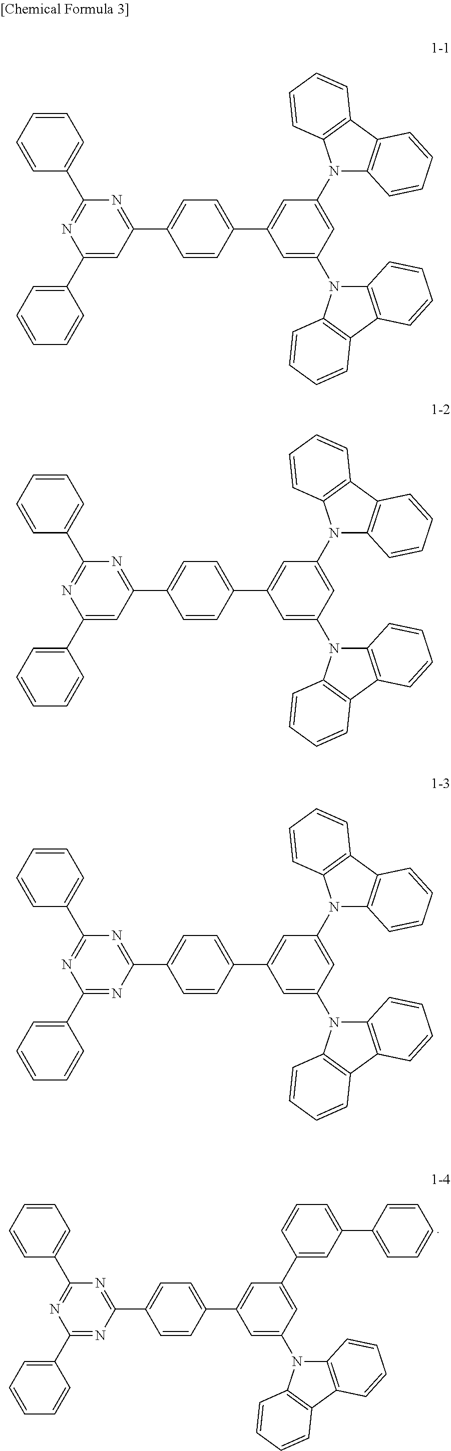 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)cc3)n2)cc1 ; c1ccc(-c2cccc(-c3cc(-c4ccc(-c5nc(-c6ccccc6)nc(-c6ccccc6)n5)cc4)cc(-n4c5ccccc5c5ccccc54)c3)c2)cc1]

The ETM1 362 having the structure of Chemical Formulae 1 to 3 has lower electron transporting properties compared to the ETM2 364. When the electron transport layer including the ETML2 362 having the structure of Chemical Formulae 1 to 3 is disposed adjacently to the second electrode 220, for example, the EIL 370, the driving voltage of the OLED is raised and the luminous efficiency and the luminous lifespan of the OLED is reduced owing to the lowering electron injection properties.

On the contrary, the ETL1 360A including the ETM1 362 with relatively low electron transporting properties is disposed adjacently to the EML 340. As the electrons transported from the ETL2 360B can be transported and injected rapidly to the EML 340, so that the driving voltage of the OLED D1 can be lowered with improving the luminous properties.

The ETL2 360B can include a second electron transporting material (ETM2) 364 of a benzimidazole-containing organic compound with beneficial electron affinity and electron transporting properties. The ETM2 364 can include a benzimidazole-containing organic compound having the following structure of Chemical Formula 4:

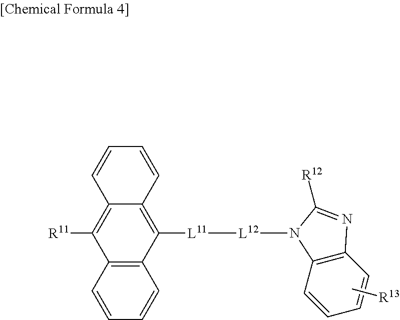

wherein, in Chemical Formula 4,
each of R¹¹ to R¹³ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
each of L¹¹ and L¹² is independently a single bond, an unsubstituted or substituted C₆-C₃₀ arylene group or an unsubstituted or substituted C₃-C₃₀ hetero arylene group, where at least one of L¹¹ and L₁₂ is not a single bond.

In one embodiment, each of the C₁-C₂₀ alkyl group, the C₆-C₃₀ aryl group and/or the C₃-C₃₀ hetero aryl group of R¹¹ to R¹³ in Chemical Formula 4 can be independently unsubstituted or substituted with at least one group selected from a C₁-C₁₀ alkyl group, a C₆-C₂₀ aryl group and a C₃-C₂₀ hetero aryl group. In another embodiment, the C₆-C₃₀ arylene group and/or the C₃-C₃₀ hetero arylene group of L¹¹ to L¹² in Chemical Formula 4 can be independently unsubstituted or substituted with at least one C₁-C₁₀ alkyl group.

For example, R¹¹ can be an unsubstituted or substituted C₆-C₃₀ aryl group (e.g., phenyl, naphthyl and/or biphenyl), R¹² can hydrogen, an unsubstituted or substituted C₁-C₁₀ alkyl group (e.g., methyl and/or ethyl) or an unsubstituted or substituted C₆-C₃₀ aryl group (e.g., phenyl and/or biphenyl), R¹³ can be hydrogen or an unsubstituted or substituted C₁-C₂₀ alkyl group, L¹¹ can be a single bond or phenylene, and/or L¹² can be phenylene. The ETM2 364 with such a molecular conformation can have the following structure of Chemical Formula 5:

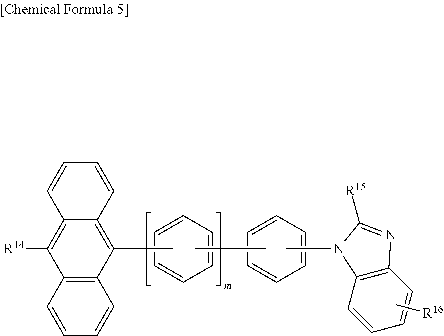

wherein, in Chemical Formula 5,
R¹⁴ is an unsubstituted or substituted C₆-C₃₀ aryl group;
R¹⁵ is hydrogen, an unsubstituted or substituted C₁-C₂₀ alkyl group or an unsubstituted or substituted C₆-C₃₀ aryl group;
R¹⁶ is hydrogen or an unsubstituted or substituted C₁-C₂₀ alkyl group; and
m is 0 or 1.

As an example, the left side phenylene moiety linked to the anthracene ring and the right side benzimidazole moiety can be linked to the right side phenylene moiety at a para-position, but is not limited thereto. For example, the ETML2 364 can be, but is not limited to, at least one of the following compounds of Chemical Formula 6:

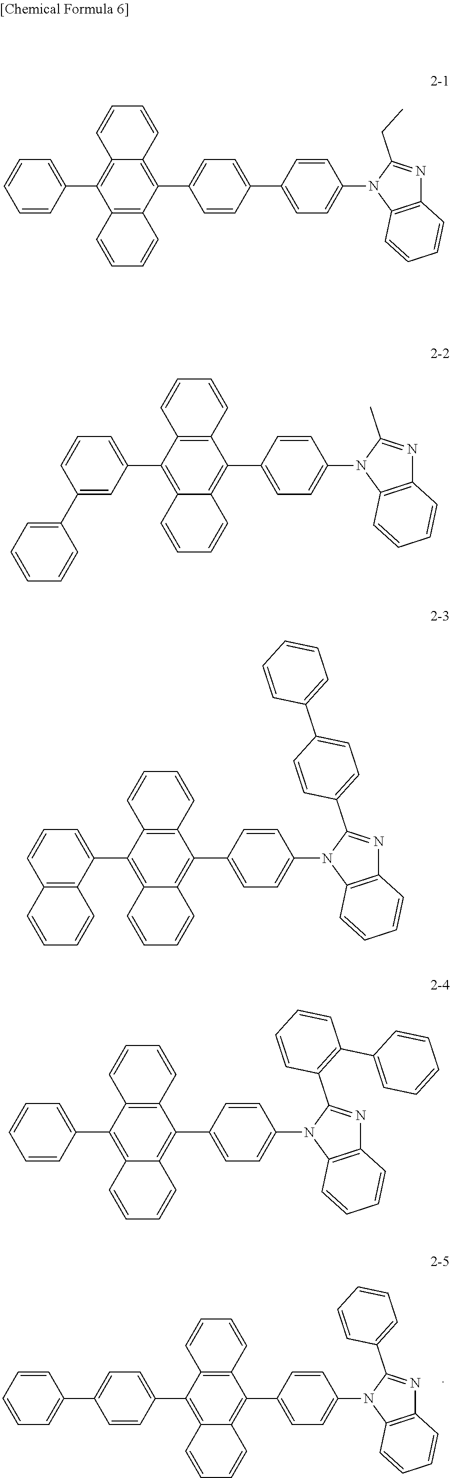 [SMILES: CCc1nc2ccccc2n1-c1ccc(-c2ccc(-c3c4ccccc4c(-c4ccccc4)c4ccccc34)cc2)cc1 ; Cc1nc2ccccc2n1-c1ccc(-c2c3ccccc3c(-c3cccc(-c4ccccc4)c3)c3ccccc23)cc1 ; c1ccc(-c2ccc(-c3nc4ccccc4n3-c3ccc(-c4c5ccccc5c(-c5cccc6ccccc56)c5ccccc45)cc3)cc2)cc1 ; c1ccc(-c2ccccc2-c2nc3ccccc3n2-c2ccc(-c3c4ccccc4c(-c4ccccc4)c4ccccc34)cc2)cc1 ; c1ccc(-c2ccc(-c3c4ccccc4c(-c4ccc(-n5c(-c6ccccc6)nc6ccccc65)cc4)c4ccccc34)cc2)cc1]

The ETM2 364 having the structure of Chemical Formulae 4 to 6 includes a benzimidazole moiety with beneficial electron affinity. In addition, the ETM2 364 includes at least one anthracenyl moiety so that the ETL1 360B can have energy level (e.g., LUMO energy level) proper to injecting electrons efficiently to the EML 340. But, when the ETL2 364 including the ETM2 364 is disposed adjacently to the EML 340, electrons are not injected efficiently to the EML 340.

On the contrary, when the ETL2 360B including the benzimidazole-containing organic compound having the structure of Chemical Formulae 4 to 6 as the ETM2 364 is spaced apart from the EML 340 and disposed adjacently to the second electrode 220 or the EIL 370, electron transportation and/or electron injection properties to the EML 340 can be improved. As the holes from the HTL 320 and electrons from the ETL 360 are injected into the EML 340 in balance, the luminous properties of the OLED D1 can be improved.

The EIL 370 is disposed between the ETL 360 and the second electrode 220 and can improve the property of the second electrode 220 and the lifespan of the OLED D1. In one embodiment, the electron injection material in the EIL 370 can be alkali metal halide material and/or alkaline earth metal halide material such as LiF, CsF, NaF, BaF₂ and the like and/or organometallic material such as lithium quinolate (Liq), lithium benzoate and sodium stearate and the like, but is not limited thereto.

In another embodiment, the electron transporting material and/or the electron injection material are mixed together to form a single layered ETL/EIL. The electron transporting material and/or the electron injecting material can be mixed, but is not limited to, a weight ratio of about 4:1 to about 1:4, for example, about 2:1 to about 1:2. For example, each of the ETL 360 and the EIL 370 can independently have a thickness, but is not limited to, about 1 nm to about 100 nm.

When holes are transferred to the second electrode 220 via the EML 340 and/or electrons are transferred to the first electrode 210 via the EML 340, the OLED D1 can have short lifespan and reduced luminous efficiency. In order to prevent those phenomena, the OLED D1 in accordance with one embodiment can have at least one exciton blocking layer adjacent to the EML 340.

For example, the OLED D1 can include the EBL 330 between the HTL 320 and the EML 340 so as to control and prevent electron transfers. In one embodiment, electron blocking material in the EBL 330 can include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof.

In addition, the OLED D1 can further include the HBL 350 as a second exciton blocking layer between the EML 340 and the ETL 360 so that holes cannot be transferred from the EML 340 to the ETL 360. In one embodiment, hole blocking material in the HBL 350 can include, but is not limited to, at least one of an oxadiazole-containing compound, a triazole-containing compound, a phenanthroline-containing compound, a benzoxazole-containing compound, a benzothiazole-containing compound, a benzimidazole-containing compound, and a triazine-containing compound.

For example, the hole blocking material in the HBL 350 can include material having a relatively low HOMO energy level compared to the luminescent materials in EML 340. The hole blocking material in the HBL 350 can include, but is not limited to, 2,9-Dimethyl-4,7-diphenyl-1,10-phenanthroline (BCP), Bis(2-methyl-8-quinolinolato-N1,08)-(1,1′-biphenyl-4-olato)aluminum (BAlq), Tris-(8-hydroxyquinolinato) aluminum (Alq₃), 2-biphenyl-4-yl-5-(4-t-butylphenyl)-1,3,4-oxadiazole (PBD), spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

In certain embodiment, the EBL 330 and/or the HBL 350 can be omitted. As an example, each of the EBL 330 and the HBL 350 can independently have a thickness of, but is not limited to, about 1 nm to about 100 nm.

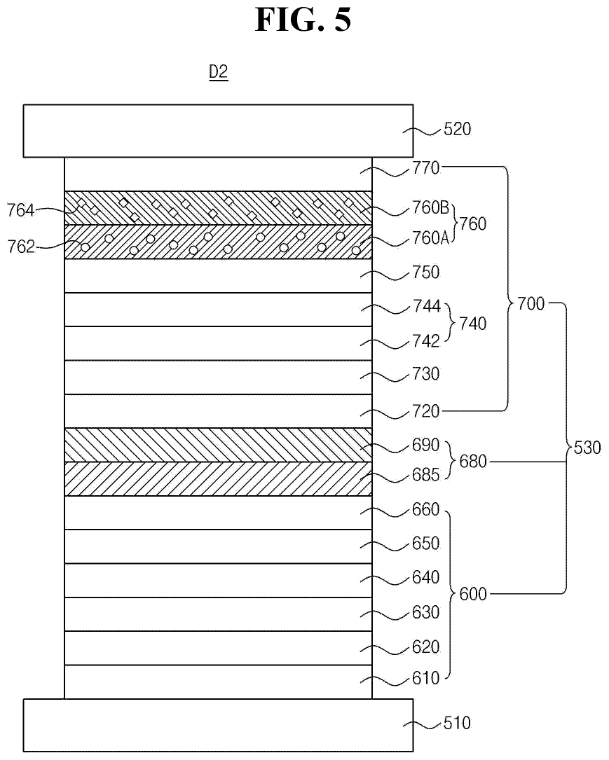

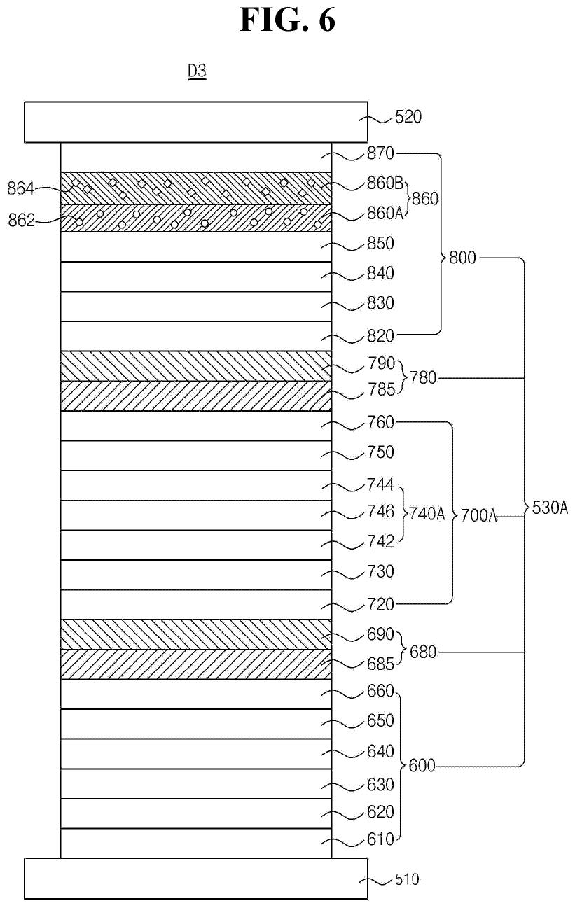

The OLED D1 with a single emitting part is shown in FIG. 3. However, the OLED can include multiple emitting parts (FIGS. 5 and 6) each of which can include an emitting material layer with identical or similar luminous peak ranges. As an example, each of the multiple emitting parts can emit red color, green color, or blue color light.

The emitting part disposed adjacently to the second electrode 220 among the multiple emitting parts can have a structure where the ETL1 360A including the ETM1 362 of the azine-containing organic compound and the ETL2 360B including the ETM2 364 of the benzimidazole-containing organic compound are disposed sequentially between the EML 340 and the second electrode 220. Accordingly, it is possible to realize a tandem-structured OLED with lowering its driving voltages with improving its luminous efficiency and luminous lifespan.

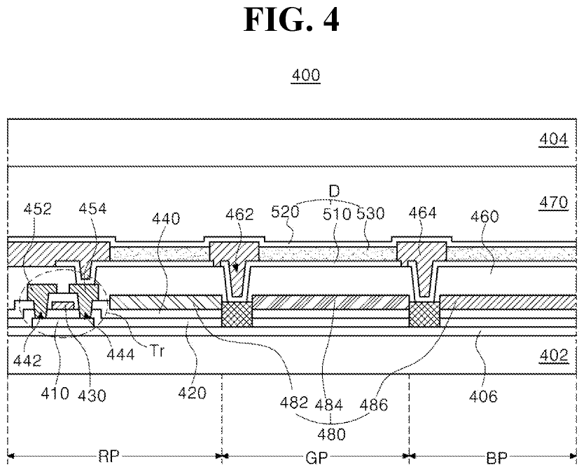

In another embodiment, an organic light emitting display device can implement full-color including white color. FIG. 4 illustrates a schematic cross-sectional view of an organic light emitting display device in accordance with another embodiment of the present disclosure.

As illustrated in FIG. 4, the organic light emitting display device 400 includes a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the first substrate 402. The organic light emitting display device 400 can include a plurality of such pixel regions arranged in a matrix configuration or other suitable configurations.

Each of the first and second substrates 402 and 404 can include, but is not limited to, glass, flexible material and/or polymer plastics. For example, each of the first substrate 402 and the second substrate 404 can be made of PI, PES, PEN, PET, PC and/or combinations thereof. The first substrate 402, on which a thin film transistor Tr and the OLED D are arranged, forms an array substrate. In certain embodiments, the second substrate 404 can be omitted.

A buffer layer 406 can be disposed on the first substrate 402. The thin film transistor Tr is disposed on the buffer layer 406 correspondingly to each of the red pixel region RP, the green pixel region GP and the blue pixel region BP. In certain embodiments, the buffer layer 406 can be omitted.

A semiconductor layer 410 is disposed on the buffer layer 406. As an example, the semiconductor layer 410 can be made of or include oxide semiconductor material or polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 including an insulating material, for example, inorganic insulating material such as SiOₓ or SiNₓ, or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

In FIG. 4, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the whole first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first electrode 510 and the second electrode 520.

The first electrode 510 formed for each pixel region RP, GP, or BP can be an anode and can include a conductive material having relatively high work function value. For example, the first electrode 510 can include, but is not limited to, ITO, IZO, ITZO, SnO, ZnO, ICO, AZO, and/or the like. In one embodiment, a reflective electrode or a reflective layer can be disposed under the first electrode 510. For example, the reflective electrode or the reflective layer can include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel region RP, the green pixel region GP and the blue pixel region BP. In certain embodiments, the bank layer 464 can be omitted.

An emissive layer 530 that can include multiple emitting parts is disposed on the first electrode 510. As illustrated in FIGS. 5 and 6, the emissive layer 530 can include multiple emitting parts 600, 700, 700A, and 800 and at least one charge generation layer 680 and 780. Each of the emitting parts 600, 700, 700A and 800 includes at least one emitting material layer and can further include an hole injection layer, a hole transport layer, an electron blocking layer, a hole blocking layer, an electron transport layer and/or an electron injection layer.

The second electrode 520 can be disposed on the first substrate 402 above which the emissive layer 530 can be disposed. The second electrode 520 can be disposed over an entire display area, can include a conductive material with a relatively low work function value compared to the first electrode 510, and can be a cathode. For example, the second electrode 520 can include, but is not limited to, Al, Mg, Ca, Ag, alloy thereof, and/or combinations thereof such as Al—Mg.

The color filter layer 480 is disposed between the first substrate 402 and the OLED D, for example, between the interlayer insulating layer 440 and the passivation layer 460. The color filter layer 480 includes a red color filter pattern 482, a green color filter pattern 484 and a blue color filter pattern 486 each of which is disposed correspondingly to the red pixel region RP, the green pixel region GP and the blue pixel region BP, respectively.

In addition, an encapsulation film 470 can be disposed on the second electrode 520 in order to prevent or reduce outer moisture from penetrating into the OLED D. The encapsulation film 470 can have, but is not limited to, a laminated structure including a first inorganic insulating film, an organic insulating film and a second inorganic insulating film (170 in FIG. 2). In addition, a polarizing plate can be attached onto the second substrate 404 to reduce reflection of external light. For example, the polarizing plate can be a circular polarizing plate.

In FIG. 4, the light emitted from the OLED D is transmitted through the first electrode 510 and the color filter layer 480 is disposed under the OLED D. The organic light emitting display device 400 can be a bottom-emission type. Alternatively, the light emitted from the OLED D is transmitted through the second electrode 520 and the color filter layer 480 can be disposed on the OLED D when the organic light emitting display device 400 is a top-emission type. In this case, the color filter layer 480 can be attached to the OLED D through an adhesive layer. Alternatively, the color filter layer 480 can be disposed directly on the OLED D. when the organic light emitting display device 400 is top-emission type, a reflective electrode or reflective layer can be formed under the first electrode 510. For example, the reflective electrode or the reflective layer can include silver or APC alloy.

In addition, a color conversion layer can be formed or disposed between the OLED D and the color filter layer 480. The color conversion layer can include a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 can comprise the color conversion film instead of the color filter layer 480.

As described above, the white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will be described in more detail. FIG. 5 illustrates a schematic cross-sectional view of an organic light emitting diode having a tandem structure of two emitting parts.

As illustrated in FIG. 5, the OLED D2 in accordance with another embodiment of the present disclosure includes first and second electrodes 510 and 520 facing each other and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

The first electrode 510 can be an anode and can include a conductive material having relatively high work function value such as TCO. For example, the first electrode 510 can include, but is not limited to, ITO, IZO, ITZO, SnO, ZnO, ICO, AZO, and/or the like. The second electrode 520 can be a cathode and can include a conductive material with a relatively low work function value. For example, the second electrode 520 can include, but is not limited to, Al, Mg, Ca, Ag, alloy thereof and/or combination thereof such as Al—Mg.

The first emitting part 600 includes a first emitting material layer (bottom or lower EML, EML1) 640. The first emitting part 600 can further include at least one of a hole injection layer (HIL) 610 disposed between the first electrode 510 and the EML1 640, a first hole transport layer (bottom or lower HTL, HTL1) 620 disposed between the HIL 610 and the EML1 640, and a bottom or lower electron transport layer (B-ETL) 660 disposed between the EML1 640 and the CGL 680. Alternatively, or additionally, the first emitting part 600 can further include a first electron blocking layer (bottom or lower EBL, EBL1) 630 disposed between the HTL1 620 and the EML1 640 and/or a first hole blocking layer (bottom or lower HBL, HBL1) 650 disposed between the EML1 640 and the B-ETL 660.

The second emitting part 700 includes a second emitting material layer (top or upper EML, EML2) 740. The second emitting part 700 can further include at least one of a second hole transport layer (top or upper HTL, HTL2) 720 disposed between the CGL 680 and the EML2 740, a top or upper electron transport layer (T-ETL) 760 disposed between the second electrode 520 and the EML2 740 and an electron injection layer (EIL) 770 disposed between the second electrode 520 and the T-ETL 760. Alternatively, or additionally, the second emitting part 700 can further include a second electron blocking layer (top or upper EBL, EBL2) 730 disposed between the HTL2 720 and the EML2 740 and/or a second hole blocking layer (top or upper HBL, HBL2) 750 disposed between the EML2 740 and the T-ETL 760.

One of the EML1 640 and the EML2 740 can emit blue color light, and the other of the EML1 640 and the EML2 740 can emit any colors with longer wavelength ranges than the blue color light, for example, red-green color light so that the OLED D2 can realize white (W) emission. Hereinafter, the OLED D2 where the EML1 640 emits blue color light and the EML2 740 emits red-green color light will be described in detail.

The HIL 610 is disposed between the first electrode 510 and the HTL1 620 and improves an interface property between the inorganic first electrode 510 and the organic HTL1 620. In one exemplary embodiment, hole injecting material in the HIL 610 can include, but is not limited to, MTDATA, NATA, 1T-NATA, 2T-NATA, CuPc, TCTA, NPB (NPD), DNTPD, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, MgF₂, CaF₂ and/or combinations thereof. Alternatively, the HIL 610 can include a host of the hole transporting material and a P-type dopant that can be HAT-CN, F4-TCNQ, F6-TCNNQ, NPD9 and/or combinations thereof. In certain embodiments, the HIL 610 can be omitted in compliance of the OLED D2 property.

In one embodiment, the hole transporting material in each of the HTL1 620 and the HTL2 720 can independently include, but is not limited to, TPD, NPB (NPD), DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-N-([1,1′-Biphenyl]-4-yl)-9,9-dimethyl-N-(4-(9-phenyl-9H-yl)phenyl)biphenyl-4-amine, carbazol-3-yl)phenyl)-9H-fluoren-2-amine and/or combination thereof.

Each of the B-ETL 660 and the T-ETL 760 facilitates electron transportation in each of the first emitting part 600 and the second emitting part 700, respectively. As an example, the electron transporting material in the B-ETL 660 can include at least one of an oxadiazole-containing compound, a triazole-containing compound, a phenanthroline-containing compound, a benzoxazole-containing compound, a benzothiazole-containing compound, a benzimidazole-containing compound, a triazine-containing compound.

For example, the electron transporting material in the B-ETL 660 can include, but is not limited to, Alq₃, PBD, spiro-PBD, Liq, TPBi, BAlq, 7-diphenyl-1,10-phenanthroline (Bphen), 2,9-Bis(naphthalene-2-yl)-4,7-diphenyl-1,10-phenanthroline (NBphen), BCP, 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)-1,3,5-triazine (TmPPPyTz), Poly[9,9-bis(3′-(N,N-dimethyl)-N-ethylammonium)-propyl)-2,7-fluorene]-alt-2,7-(9,9-dioctylfluorene)] (PFNBr), Tris(phenylquinoxaline) (TPQ), TSPO1, 2-[4-(9,10-di-2-naphthalen-2-yl-2-anthracen-2-yl)phenyl]-1-phenyl-1H-benzimidazole (ZADN) and/or combinations thereof.

The T-ETL 760 includes a first electron transport layer (ETL1) 760A and a second electron transport layer (ETL2) 760B disposed sequentially between the EML2 740 and the second electrode 520 or the EIL 770. The ETL1 760A disposed adjacently to the EML2 740 includes a first electron transporting material (ETM1) 762 of the azine-containing organic compound having the structure of Chemical Formulae 1 to 3. The ETL2 760B disposed on the ETL1 760A includes a second electron transporting material (ETM2) 764 of the benzimidazole-containing organic compound having the structure of Chemical Formulae 4 to 6. The ETL1 760A including the ETM1 762 with relatively low electron transportation properties is disposed adjacently to the EML2 740 and the ETL2 760B including the ETM2 764 with beneficial electron transportation properties is disposed adjacently to the second electrode 220, the driving voltage of the OLED D2 can be lowered and the luminous efficiency and the luminous lifespan of the OLED D2 can be improved.

The EIL 770 is disposed between the second electrode 520 and the T-ETL 760, and can improve physical properties of the second electrode 520 and therefore, can enhance the lifespan of the OLED D2. In one embodiment, electron injecting material in the EIL 770 can include an alkali metal halide and/or alkaline earth metal halides such as LiF, CaF, NaF, BaF₂ and the like and/or organometallic material such as Liq, lithium benzoate, sodium benzoate and the like.

Electron blocking material in each of the EBL1 630 and the EBL2 730 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Hole blocking material in each of the HBL1 650 and the HBL2 750 can include, but is not limited to, at least one of an oxadiazole-containing compound, a triazole-containing compound, a phenanthroline-containing compound, a benzoxazole-containing compound, a benzothiazole-containing compound, a benzimidazole-containing compound, and a triazine-containing compound. For example, the hole blocking material in each of the HBL1 650 and the HBL2 750 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL 680 is disposed between the first emitting part 600 and the second emitting part 700. The CGL 680 includes an N-type charge generation layer (N-CGL) 685 disposed between the B-ETL 660 and the HTL2 720 and a P-type charge generation layer (P-CGL) 690 disposed between the N-CGL 685 and the HTL2 720. The N-CGL 685 injects electrons to the EML1 640 of the first emitting part 600 and the P-CGL 690 injects holes to the EML2 740 of the second emitting part 700.

In one embodiment, the N-CGL 685 can be an organic layer where electron transporting material doped with an alkali metal such as Li, Na, K and Cs and/or an alkaline earth metal such as Mg, Sr, Ba and Ra. For example, the contents of the alkali metal and/or the alkaline earth metal in the N-CGL 685 can be about 0.01 wt. % to about 30 wt. %.

In one embodiment, the P-CGL 690 can include, but is not limited to, inorganic material selected from the group consisting of WOₓ, MoOₓ, Be₂O₃, V₂O₅ and combinations thereof. In another embodiment, the P-CGL 690 can include, but is not limited to, hole transporting material (e.g., NPD, TPD, DNTPD) and/or hole injecting material (e.g., HAT-CN, F4-TCNQ, F6-TCNNQ). As an example, the P-CGL 690 include a host of hole transporting material such as NPD, DNTPD, TPD, TFB, TCTA and/or combinations thereof and a P-type dopant such as F4-TCNQ, F6-TCNQ, NPD-9 and/or combinations thereof. The contents of the P-type dopant in the P-CGL 690 can be, but is not limited to, about 1 wt. % to about 30 wt. %, for example, about 3 wt. % to about 25 wt. %.

In the OLED D2, the EML1 640 can be a blue emitting material layer. In this case, the EML1 640 can be a blue emitting material layer, a sky-blue emitting material layer or a deep-blue emitting material layer. The EML1 640 can include a blue host and a blue emitter. The blue host can include a P-type blue host and/or an N-type blue host. The blue emitter can include at least one of blue phosphorescent material, blue fluorescent material and blue delayed fluorescent material. The blue host and the blue emitter can be identical to corresponding materials with referring to FIG. 3.

The EML2 740 can include a first layer 742 disposed between the EBL2 730 and the HBL2 750 and a second layer 744 disposed between the first layer 742 and the HBL2 750. One of the first layer 742 and the second layer 744 can emit red color light and the other of the first layer 742 and the second layer 744 can emit green color light. Hereinafter, the EML2 740 where the first layer 742 emits a red color light and the second layer 744 emits a green color light will be described in detail.

The first layer 742 can include a red host and a red emitter. The red host can include a P-type red host and/or an N-type red host. The red emitter can include at least one of red phosphorescent material, red fluorescent material and red delayed fluorescent material. The red host and the red dopant can be identical to corresponding materials with referring to FIG. 3.

The second layer 744 can include a green host and a green emitter. The green host can include a P-type green host and/or an N-type green host. The green emitter can include at least one of green phosphorescent material, green florescent material and green delayed fluorescent material. The green host and the green emitter can be identical to corresponding materials with referring to FIG. 3.

As an example, the contents of the host in each of the EML1 640 and the EML2 740 can be, but is not limited to, between about 50 wt. % and about 99 wt. %, for example, about 80 wt. % and about 95 wt. %, and the contents of the emitter in each of the EML1 640 and the EML2 740 can be, but is not limited to, between about 1 wt. % and about 50 wt. %, for example, about 5 wt. % and about 20 wt. %. When each of the EML1 640 and the EML2 740 includes both the P-type host and the N-type host, the P-type host and the N-type host can be admixed, but is not limited to, with a weight ratio from about 4:1 to about 1:4, for example, about 3:1 to about 1:3. Alternatively, or additionally, the EML2 740 can further include a third layer (746 in FIG. 6) that can emit yellow-green color light disposed between the first layer 742 and the second layer 744.

An OLED can have three or more emitting parts to form a tandem structure. FIG. 6 is a schematic cross-sectional view illustrating an organic light emitting diode in accordance with yet another embodiment of the present disclosure.

As illustrated in FIG. 6, the OLED D3 includes first and second electrodes 510 and 520 facing each other and an emissive layer 530A disposed between the first and second electrodes 510 and 520. The emissive layer 530A includes a first emitting part 600 disposed between the first electrode 510 and the second electrode 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

The first emitting part 600 includes a first emitting material layer (bottom or lower EML, EML1) 640. The first emitting part 600 can further include at least one of an hole injection layer (HIL) 610 disposed between the first electrode 510 and the EML1 640, a first hole transport layer (bottom or lower HTL, HTL1) 620 disposed between the HIL 610 and the EML1 640, a bottom electron transport layer (B-ETL) 660 disposed between the EML1 640 and the CGL1 680. Alternatively, or additionally, the first emitting part 600 can further comprise a first electron blocking layer (bottom or lower EBL, EBL1) 630 disposed between the HTL1 620 and the EML1 640 and/or a first hole blocking layer (bottom or lower HBL, HBL1) 650 disposed between the EML1 640 and the B-ETL 660.

The second emitting part 700A includes a second emitting material layer (middle EML, EML2) 740A. The second emitting part 700A can further include at least one of a second hole transport layer (middle HTL, HTL2) 720 disposed between the CGL1 680 and the EML2 740A and a middle electron transport layer (M-ETL) 760 disposed between the EML2 740A and the CGL2 780. Alternatively, or additionally, the second emitting part 700A can further include a second electron blocking layer (middle EBL, EBL2) 730 disposed between the HTL2 720 and the EML2 740A and/or a second hole blocking layer (middle HBL, HBL2) 750 disposed between the EML2 740A and the M-ETL 760.

The third emitting part 800 includes a third emitting material layer (top or upper EML, EML3) 840. The third emitting part 800 can further include at least one of a third hole transport layer (top or upper HTL, HTL3) 820 disposed between the CGL2 780 and the EML3 840, a top or upper electron transport layer (T-ETL) 860 disposed between the second electrode 520 and the EML3 840 and an electron injection layer (EIL) 870 disposed between the second electrode 520 and the T-ETL 860. Alternatively, or additionally, the third emitting part 800 can further comprise a third electron blocking layer (top or upper EBL, EBL3) 830 disposed between the HTL3 820 and the EML3 840 and/or a third hole blocking layer (top or upper HBL, HBL3) 850 disposed between the EML3 840 and the T-ETL 860.

At least one of the EML1 640, the EML2 740A and the EML3 840 can emit red-green color light, and another of the EML1 640, the EML2 740A and the EML3 840 can emit a blue color light so that the OLED D3 can realize white emission. Hereinafter, the OLED where the EML2 740A emits red-green color light will be described in detail.

In one exemplary embodiment, hole injecting material in the HIL 610 can include, but is not limited to, MTDATA, NATA, 1T-NATA, 2T-NATA, CuPc, TCTA, NPB (NPD), DNTPD, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, MgF₂, CaF₂ and/or combinations thereof. Alternatively, the HIL 610 can include a host of the hole transporting material and a P-type dopant that can be HAT-CN, F4-TCNQ, F6-TCNNQ, NPD9 and/or combinations thereof. In certain embodiments, the HIL 610 can be omitted in compliance of the OLED D3 property.

Hole transporting material in each of the HTL1 620, the HTL2 720 and the HTL3 820 can include independently, but is not limited to, TPD, NPB (NPD), DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

Each of the B-ETL 660, the M-ETL 760 and the T-ETL 860 provides electron transportation in each of the first emitting part 600, the second emitting part 700A and the third emitting part 800, respectively.

In one embodiment, electron transporting material in each of the B-ETL 660 and the M-ETL 760 can independently include at least one of an oxadiazole-containing compound, a triazole-containing compound, a phenanthroline-containing compound, a benzoxazole-containing compound, a benzothiazole-containing compound, a benzimidazole-containing compound, a triazine-containing compound. For example, electron transporting material in each of the B-ETL 660 and the M-ETL 760 can independently include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The T-ETL 860 includes a first electron transport layer (ETL1) 860A and a second electron transport layer (ETL2) 860B disposed sequentially between the EML3 840 and the second electrode 520 or the EIL 870. The ETL1 860A disposed adjacently to the EML3 840 includes a first electron transporting material (ETM1) 862 of the azine-containing organic compound having the structure of Chemical Formulae 1 to 3. The ETL2 860B disposed on the ETL1 860A includes a second electron transporting material (ETM2) 864 of the benzimidazole-containing organic compound having the structure of Chemical Formulae 4 to 6. The ETL1 860A including the ETM1 862 with controlled electron transportation properties and energy level is disposed adjacently to the EML3 840 and the ETL2 860B including the ETM2 864 with beneficial electron transportation properties is disposed adjacently to the second electrode 520, the driving voltage of the OLED D3 can be lowered and the luminous efficiency and the luminous lifespan of the OLED D2 can be improved.

Electron blocking material in each of the EBL1 630, the EBL2 730 and the EBL3 830 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Hole blocking material in each of the HBL1 650, the HBL2 750 and the HBL3 850 can include independently at least one of an oxadiazole-containing compound, a triazole-containing compound, a phenanthroline-containing compound, a benzoxazole-containing compound, a benzothiazole-containing compound, a benzimidazole-containing compound, a triazine-containing compound.

The CGL1 680 is disposed between the first emitting part 600 and the second emitting part 700A and the CGL2 780 is disposed between the second emitting part 700A and the third emitting part 800. The CGL1 680 includes a first N-type charge generation layer (N-CGL1) 685 disposed between the B-ETL 660 and the HTL2 720 and a first P-type charge generation layer (P-CGL1) 690 disposed between the N-CGL1 685 and the HTL2 720. The CGL2 780 includes a second N-type charge generation layer (N-CGL2) 785 disposed between the M-ETL 760 and the HTL3 820 and a second P-type charge generation layer (P-CGL2) 790 disposed between the N-CGL2 785 and the HTL3 820. Each of the N-CGL1 685 and the N-CGL2 785 injects electrons to the EML1 640 of the first emitting part 600 and the EML2 740A of the second emitting part 700A, respectively, and each of the P-CGL1 690 and the P-CGL2 790 injects holes to the EML2 740A of the second emitting part 700A and the EML3 840 of the third emitting part 800, respectively. Each of the N-CGL1 685 and the N-CGL2 785, and the P-CGL1 690 and the P-CGL2 790 can have the same configurations with referring to FIG. 5.

In one embodiment, the EIL 870 can include an alkali metal halide and/or alkaline earth metal halides such as LiF, CaF, NaF, BaF₂ and the likes and/or organometallic material such as Liq, lithium benzoate, sodium benzoate and the likes.

Each of the EML1 640 and the EML3 840 can be independently a blue emitting material layer. In this case, each of the EML1 640 and the EML3 840 can be independently a blue emitting material layer, a sky-blue emitting material layer or a deep-blue emitting material layer. Each of the EML1 640 and the EML3 840 can independently include a blue host and a blue emitter. Each of the blue host and the blue emitter can be identical to each of the blue host and the blue dopant with referring to FIG. 3. For example, the blue emitter can include at least one of the blue phosphorescent materials, the blue fluorescent materials and the blue delayed fluorescent materials. Alternatively, the blue emitter in the EML1 640 can be identical to or different from the blue emitter in the EML3 840 in terms of color and/or luminous efficiency.

The EML2 740A can include a first layer 742, a third layer 746 and a second layer 744 disposed sequentially between the EBL2 730 and the HBL2 750. One of the first layer 742 and the second layer 744 can emit red color light and the other of the first layer 742 and the second layer 744 can emit green color light. Hereinafter, the EML2 740A where the first layer 742 emits a red color light and the second layer 744 emits a green color light will be described in detail.

The first layer 742 can include a red host and a red emitter. Each of the red host and the red emitter can be identical to corresponding materials with referring to FIG. 3. For example, the red emitter can include at least one of the red phosphorescent materials, the red fluorescent materials and the red delayed fluorescent materials.

The second layer 744 can include a green host and a green emitter. Each of the green host and the green emitter can be identical to corresponding material with referring to FIG. 3. For example, the green emitter can include at least one of the green phosphorescent materials, the green fluorescent materials and the green delayed fluorescent materials.

The third layer 746 can be a yellow-green emitting material layer. The third layer 746 can include a yellow-green host and a yellow-green emitter. As an example, the yellow-green host can include a P-type yellow-green host and/or an N-type yellow-green host. As an example, the yellow-green host can include the red host and/or the green host. The yellow-green emitter can include at least one of yellow-green phosphorescent materials, yellow-green fluorescent materials and yellow-green delayed fluorescent materials.

As an example, the yellow-green emitter can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethyl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof. In certain embodiments, the third layer 746 can be omitted.

### EXAMPLES

The following examples are not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### Example 1 (Ex. 1): Fabrication of OLED

An organic light emitting diode where a first electron transport layer including Compound 1-1 of Chemical Formula 3 of an azine-containing organic compound and a second electron transport layer including Compound 2-1 of Chemical Formula 6 of a benzimidazole-containing organic compound are disposed between an emitting material layer and a cathode was fabricated. A glass substrate onto which ITO (100 nm) was coated as a thin film was washed and ultrasonically cleaned by solvent such as isopropyl alcohol, acetone and dried at 100° C. oven. The substrate was transferred to a vacuum chamber for depositing emissive layer. Subsequently, an emissive layer and a cathode were deposited by evaporation from a heating boat under about 5-7×10⁻⁷ Torr as the following order:

Hole injection layer (HIL, DNTPD (80 wt. %), P-type dopant (20 wt. %), 10 nm); hole transport layer (HTL, DNTPD, 100 nm); electron blocking layer (EBL, TCTA, 5 nm); emitting material layer (EML, (MADN (95 wt. %), DABNA-1 (5 wt. %), 20 nm); first electron transport layer (ETL1, Compound of 1-1 of Chemical Formula 3, 10 nm); second electron transport layer (ETL2, Compound of 2-1 of Chemical Formula 6, 10 nm); electron injection layer (EIL, LIF, 1.5 nm); and a cathode (Al, 100 nm).

The structures of materials used in the HIL, HTL, EBL and the host and the dopant in the EML among the compounds used for preparing the OLED are illustrated in the following:

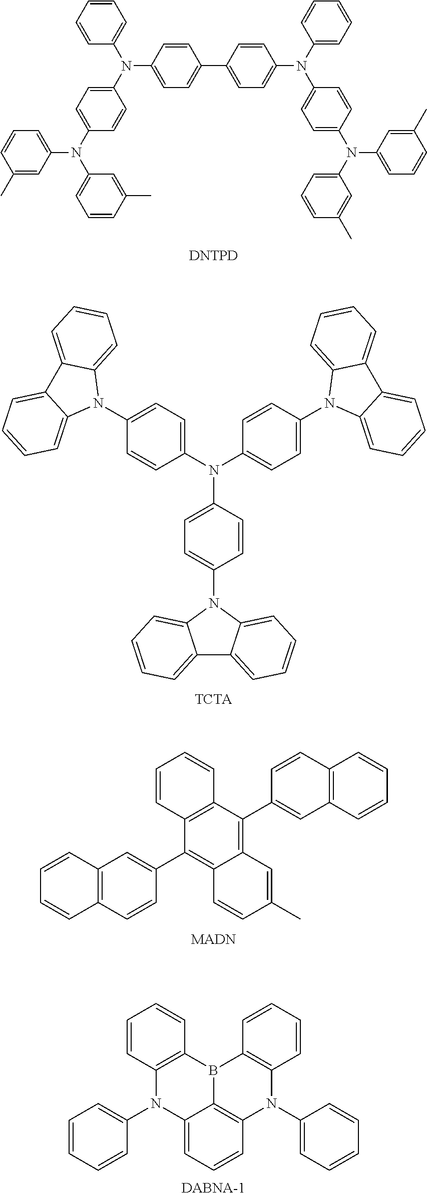

### Examples 2-5 (Ex. 2-5): Fabrication of OLEDs

An OLED was fabricated using the same procedure and the same material as Example 1, except that Compound 2-2 (Ex. 2), Compound 2-3 (Ex. 3), Compound 2-4 (Ex. 4) and Compound 2-5 (Ex. 5) in Chemical Formula 6 instead of Compound 2-1 in the ETL2 were used as the second electron transporting material.

### Example 6 (Ex. 6): Fabrication of OLEDs

An OLED was fabricated using the same procedure and the same material as Example 1, except that Compound 1-2 in Chemical Formula 3 instead of Compound 1-1 in the ETL1 was used as the first electron transporting material.

### Examples 7-10 (Ex. 7-10): Fabrication of OLEDs

An OLED was fabricated using the same procedure and the same material as Example 6, except that Compound 2-2 (Ex. 7), Compound 2-3 (Ex. 8), Compound 2-4 (Ex. 9) and Compound 2-5 (Ex. 10) in Chemical Formula 6 instead of Compound 2-1 were used as the second electron transporting material.

### Example 11 (Ex. 11): Fabrication of OLEDs

An OLED was fabricated using the same procedure and the same material as Example 1, except that Compound 1-3 in Chemical Formula 3 instead of Compound 1-1 in the ETL1 was used as the first electron transporting material.

### Examples 12-15 (Ex. 12-15): Fabrication of OLEDs

An OLED was fabricated using the same procedure and the same material as Example 11, except that Compound 2-2 (Ex. 12), Compound 2-3 (Ex. 13), Compound 2-4 (Ex. 14) and Compound 2-5 (Ex. 15) in Chemical Formula 6 instead of Compound 2-1 were used as the second electron transporting material.

### Example 16 (Ex. 16): Fabrication of OLEDs

An OLED was fabricated using the same procedure and the same material as Example 1, except that Compound 1-4 in Chemical Formula 3 instead of Compound 1-1 in the ETL1 was used as the first electron transporting material.

### Examples 17-20 (Ex. 17-20): Fabrication of OLEDs

An OLED was fabricated using the same procedure and the same material as Example 16, except that Compound 2-2 (Ex. 17), Compound 2-3 (Ex. 18), Compound 2-4 (Ex. 19) and Compound 2-5 (Ex. 20) in Chemical Formula 6 instead of Compound 2-1 were used as the second electron transporting material.

### Comparative Examples 1-9 (Ref. 1-9): Fabrication of OLEDs

An OLED was fabricated using the same procedure and the same material as Example 1, except that the double-layered electron transport layer was modified to a single-layered electron transport layer. The electron transporting material in the single-layered electron transport layer was Compound 1-1 (Ref. 1), Compound 1-2 (Ref. 2), Compound 1-3 (Ref. 3), Compound 1-4 (Ref. 4) in Chemical Formula 3, Compound 2-1 (Ref. 5), Compound 2-2 (Ref. 6), Compound 2-3 (Ref. 7), Compound 2-4 (Ref. 8) and Compound 2-5 (Ref. 10) in Chemical Formula 6.

### Experimental Example 1: Measurement of Luminous Property of OLEDs

The luminous properties for each of the OLEDs, fabricated in Examples 1 to 20 and Comparative Examples 1 to 9, were measured. Each of the OLEDs were connected to an external power source and then luminous properties for all the OLEDs were evaluated using a constant current source (KEITHLEY) and a photometer PR650 at room temperature. In particular, driving voltage (V) and External quantum efficiency (EQE) at a current density of 10 mA/cm², and time period (LT₉₅) at which the luminance of the red color light was reduced to 95% from initial luminance as luminous lifespan were measured at a current density 40 mA/cm² and at 40° C. The measurement results for the OLEDs fabricated in Examples 1 to 20 are indicated in the following Table 1, and the measurement results for the OLEDs fabricated in Comparative Examples 1 to 9 are indicated in the following Table 2.

TABLE 1
Luminous Property of OLED

| Sample | ETL1 | ETL2 | V | EQE | LT₉₅ |
|---|---|---|---|---|---|
| Ex. 1 | 1-1 | 2-1 | 3.79 | 7.0 | 52 |
| Ex. 2 | 1-1 | 2-2 | 3.77 | 7.2 | 49 |
| Ex. 3 | 1-1 | 2-3 | 3.70 | 7.5 | 51 |
| Ex. 4 | 1-1 | 2-4 | 3.73 | 7.3 | 57 |
| Ex. 5 | 1-1 | 2-5 | 3.75 | 7.4 | 63 |
| Ex. 6 | 1-2 | 2-1 | 3.70 | 7.2 | 56 |
| Ex. 7 | 1-2 | 2-2 | 3.69 | 6.9 | 56 |
| Ex. 8 | 1-2 | 2-3 | 3.72 | 6.8 | 59 |
| Ex. 9 | 1-2 | 2-4 | 3.71 | 7.1 | 60 |
| Ex. 10 | 1-2 | 2-5 | 3.76 | 7.1 | 57 |
| Ex. 11 | 1-3 | 2-1 | 3.72 | 8.1 | 42 |
| Ex. 12 | 1-3 | 2-2 | 3.68 | 8.0 | 41 |
| Ex. 13 | 1-3 | 2-3 | 3.71 | 7.8 | 45 |
| Ex. 14 | 1-3 | 2-4 | 3.69 | 8.2 | 48 |
| Ex. 15 | 1-3 | 2-5 | 3.63 | 7.8 | 49 |
| Ex. 16 | 1-4 | 2-1 | 3.63 | 7.8 | 46 |
| Ex. 17 | 1-4 | 2-2 | 3.60 | 8.2 | 43 |
| Ex. 18 | 1-4 | 2-3 | 3.61 | 8.4 | 45 |
| Ex. 19 | 1-4 | 2-4 | 3.63 | 8.0 | 39 |
| Ex. 20 | 1-4 | 2-5 | 3.71 | 7.9 | 40 |

TABLE 2
Luminous Property of OLED

| Sample | ETL | V | EQE | LT₉₅ |
|---|---|---|---|---|
| Ref. 1 | 1-1 | 7.12 | 3.4 | 15 |
| Ref. 2 | 1-2 | 6.91 | 3.2 | 11 |
| Ref. 3 | 1-3 | 6.85 | 3.5 | 13 |
| Ref. 4 | 1-4 | 7.21 | 3.0 | 12 |
| Ref. 5 | 2-1 | 3.65 | 6.7 | 19 |
| Ref. 6 | 2-2 | 3.72 | 6.5 | 16 |
| Ref. 7 | 2-3 | 3.61 | 6.3 | 17 |
| Ref. 8 | 2-4 | 3.59 | 6.4 | 15 |
| Ref. 9 | 2-5 | 3.68 | 6.6 | 18 |

As indicated in Tables 1 and 2, the driving voltage was lowered and EQE and luminous lifespan were improved significantly in the OLEDs fabricated in Examples 1 to 20. Particularly, compared to the OLEDs fabricated in Comparative Examples 1-4 where the single-layered electron transport layer includes the azine-containing electron transporting material, in the OLEDs fabricated in Examples 1 to 20 where the double-layered electron transport layer was applied, the driving voltage was lowered by 50.1% maximally, and EQE and the luminous lifespan were improved by 180% maximally and by 472.7% maximally, respectively. Compared to the OLEDs fabricated in Comparative Examples 5-9 where the single-layered electron transport layer includes the benzimidazole-containing electron transporting material, in the OLEDs fabricated in Examples 1 to 20, the driving voltage was maintained at an equivalent level, and EQE and the luminous lifespan was improved by 33.3% maximally and by 320% maximally, respectively.

### Comparative Examples 10-17 (Ref. 10-17): Fabrication of OLEDs

An OLED was fabricated using the same procedure and the same material as Example 1, except that the ETL1 included the benzimidazole-containing compounds in Chemical Formula 6 and the ETL2 included the azine-containing compounds in Chemical Formula 3. The following Table 2 indicates the compounds used in the ETL1 and the ETL2 in Comparative Examples 10 to 17.

### Experimental Example 2: Measurement of Luminous Property of OLEDs

The luminous properties for each of the OLEDs fabricated in Comparative Examples 10 to 17 were measured as Experimental Example 1. The measurement results are indicated in the following Table 3.

TABLE 3
Luminous Property of OLED

| Sample | ETL1 | ETL2 | V | EQE | LT₉₅ |
|---|---|---|---|---|---|
| Ref. 10 | 2-1 | 1-1 | 6.93 | 2.9 | 10 |
| Ref. 11 | 2-1 | 1-2 | 6.89 | 3.1 | 9 |
| Ref. 12 | 2-1 | 1-3 | 7.02 | 3.3 | 12 |
| Ref. 13 | 2-1 | 1-4 | 6.89 | 3.0 | 8 |
| Ref. 14 | 2-2 | 1-1 | 6.95 | 2.8 | 12 |
| Ref. 15 | 2-2 | 1-2 | 7.13 | 3.0 | 11 |
| Ref. 16 | 2-2 | 1-3 | 6.72 | 3.1 | 12 |
| Ref. 17 | 2-2 | 1-4 | 7.17 | 3.2 | 9 |

As indicated in Tables 1 and 3, compared to the OLEDs fabricated in Comparative Examples 10 to 17 where the ETL 1 included the benzimidazole-containing organic compound and the ETL2 included the azine-containing organic compound, in the OLEDs fabricated in Examples 1 to 20 where the ETL1 adjacent to the EML included the azine-containing organic compound and the ETL2 adjacent to the cathode included the benzimidazole-containing organic compound, the driving voltage was lowered by 49.8% maximally, and EQE and the luminous lifespan were improved by 200% maximally and by 600% maximally, respectively.

### Examples 21-25 (Ex. 21-25): Fabrication of OLEDs

An OLED was fabricated using the same procedure and the same material as Example 1, except that each of the thicknesses of the ETL1 and ETL2 were modified to 40 nm and 160 nm (Ex. 21), 80 nm and 120 nm (Ex. 22), 100 nm and 100 nm (Ex. 23), 120 nm and 160 nm (Ex. 24) and 160 nm and 40 nm (Ex. 25), respectively.

### Experimental Example 3: Measurement of Luminous Property of OLEDs

The luminous properties for each of the OLEDs fabricated in Examples 21 to 25 were measured as Experimental Example 1. The measurement results are indicated in the following Table 4.

TABLE 4
Luminous Property of OLED

| Sample | ETL1 (nm) | ETL2 (nm) | V | EQE | LT₉₅ |
|---|---|---|---|---|---|
| Ex. 21 | 1-1 (40) | 2-1 (160) | 3.68 | 7.3 | 46 |
| Ex. 22 | 1-1 (80) | 2-1 (120) | 3.74 | 7.1 | 48 |
| Ex. 23 | 1-1 (100) | 2-1 (100) | 3.81 | 7.2 | 52 |
| Ex. 24 | 1-1 (120) | 2-1 (80) | 3.83 | 7.0 | 57 |
| Ex. 25 | 1-1 (160) | 2-1 (40) | 3.88 | 6.9 | 60 |

As indicated in Table 4, as the thickness of the ETL2 including the benzimidazole-containing electron transporting material compared to the thickness of the ETL1 including the azine-containing electron transporting material increased, the driving voltage was reduced and EQE was increased. On the contrary, as the thickness of the ETL1 compared to the thickness of the ETL2 increased, the luminous lifespan was increased.

Summing up the results indicated in Tables 1 to 4, when the ETL1 relative adjacent to the emitting material layer included the azine-containing electron transporting material having the structure of Chemical Formulae 1 to 3, and the ETL2 relative adjacent to the second electrode or electron injection layer includes the benzimidazole-containing electron transporting material having the structure of Chemical Formulae 4 to 6, the driving voltage was lowered with improving the luminous efficiency and the luminous lifetime.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. An organic light emitting diode comprising:
a first electrode;
a second electrode; and
an emissive layer disposed between the first electrode and the second electrode, and comprising at least one emitting part,
wherein one of the at least one emitting part is disposed adjacently to the second electrode and comprises:
at least one emitting material layer; and
an electron transport layer disposed between the at least one emitting material layer and the second electrode,
wherein the electron transport layer comprises:
a first electron transport layer disposed between the at least one emitting material layer and the second electrode; and
a second electron transport layer disposed between the first electron transport layer and the second electrode,
wherein the first electron transport layer comprises a first electron transporting material having the following structure of Chemical Formula 1, and
wherein the second electron transport layer comprises a second electron transporting material having the following structure of Chemical Formula 4: 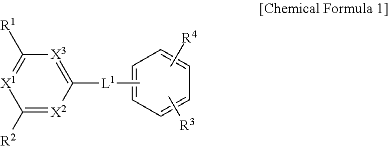
wherein, in Chemical Formula 1,
each of X¹ to X³ is independently CR⁵ or N, where at least two of X¹ to X³ is N;
each of R¹ to R⁵ is independently hydrogen, an unsubstituted or substituted C₁-C₂₀ alkyl group or an unsubstituted or substituted C₆-C₃₀ aryl group or an unsubstituted or substituted C₃-C₃₀ hetero aryl group, where at least one of R³ and R⁴ has an unsubstituted or substituted carbazolyl moiety; and
L¹ is a single bond, an unsubstituted or substituted C₆-C₃₀ arylene group or an unsubstituted or substituted C₃-C₃₀ hetero arylene group, 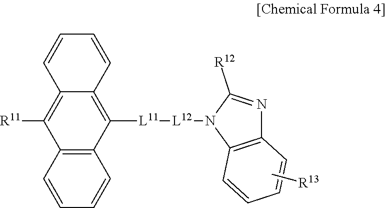
wherein, in Chemical Formula 4,
each of R¹¹ to R¹³ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
each of L¹¹ and L¹² is independently a single bond, an unsubstituted or substituted C₆-C₃₀ arylene group or an unsubstituted or substituted C₃-C₃₀ hetero arylene group, where at least one of L¹¹ and L¹² is not a single bond.

2. The organic light emitting diode of claim 1, wherein the first electron transporting material has a structure of Chemical Formula 2: 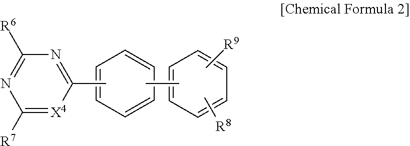
wherein, in Chemical Formula 2,
X⁴ is CR¹⁰ or N;
each of R⁶ and R⁷ is independently an unsubstituted or substituted C₆-C₃₀ aryl group;
each of R⁸ and R⁹ is independently an unsubstituted or substituted C₆-C₃₀ aryl group or an unsubstituted or substituted C₃-C₃₀ hetero aryl group, where at least one of R⁸ and R⁹ comprises an unsubstituted or substituted carbazolyl moiety; and
R¹⁰ is hydrogen or an unsubstituted or substituted C₁-C₂₀ alkyl group.

3. The organic light emitting diode of claim 1, wherein the first electron transporting material is at least one of the following organic compounds:

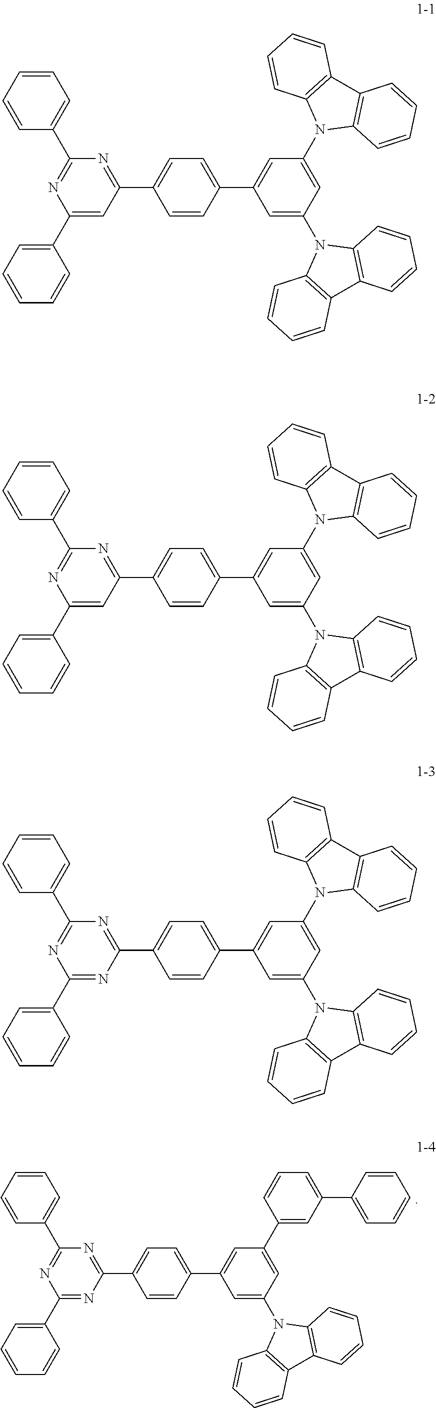 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)cc3)n2)cc1 ; c1ccc(-c2cccc(-c3cc(-c4ccc(-c5nc(-c6ccccc6)nc(-c6ccccc6)n5)cc4)cc(-n4c5ccccc5c5ccccc54)c3)c2)cc1]

4. The organic light emitting diode of claim 1, wherein the second electron transporting material has a structure of Chemical Formula 5: 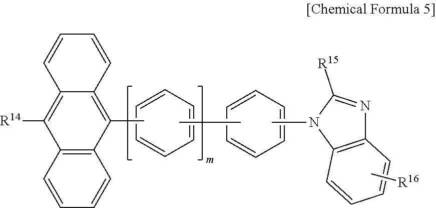
wherein, in Chemical Formula 5,
R¹⁴ is an unsubstituted or substituted C₆-C₃₀ aryl group;
R¹⁵ is hydrogen, an unsubstituted or substituted C₁-C₂₀ alkyl group or an unsubstituted or substituted C₆-C₃₀ aryl group;
R¹⁶ is hydrogen or an unsubstituted or substituted C₁-C₂₀ alkyl group; and
m is 0 or 1.

5. The organic light emitting diode of claim 1, wherein the second electron transporting material is at least one of the following compounds:

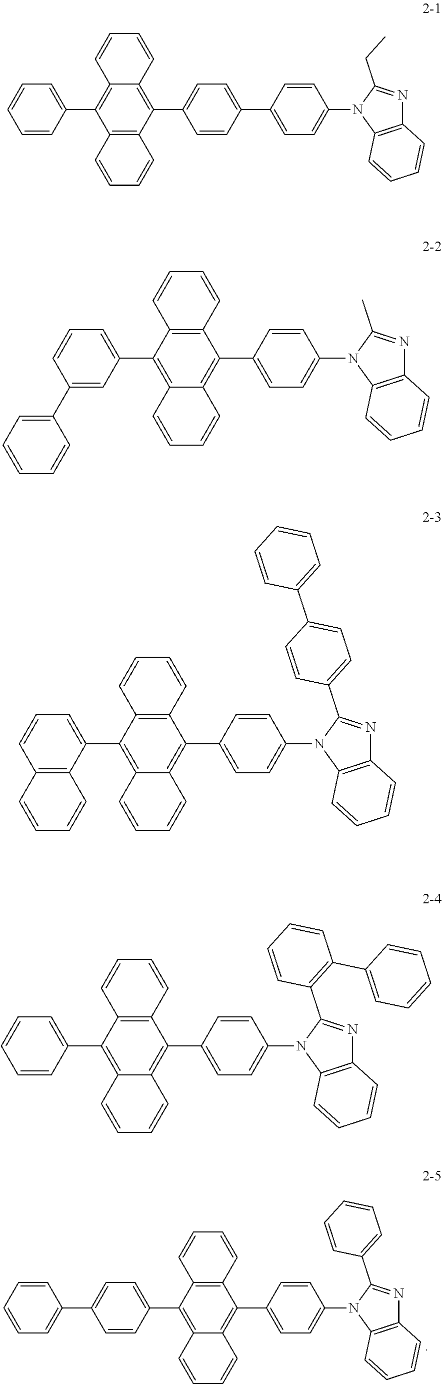 [SMILES: CCc1nc2ccccc2n1-c1ccc(-c2ccc(-c3c4ccccc4c(-c4ccccc4)c4ccccc34)cc2)cc1 ; Cc1nc2ccccc2n1-c1ccc(-c2c3ccccc3c(-c3cccc(-c4ccccc4)c3)c3ccccc23)cc1 ; c1ccc(-c2ccc(-c3nc4ccccc4n3-c3ccc(-c4c5ccccc5c(-c5cccc6ccccc56)c5ccccc45)cc3)cc2)cc1 ; c1ccc(-c2ccccc2-c2nc3ccccc3n2-c2ccc(-c3c4ccccc4c(-c4ccccc4)c4ccccc34)cc2)cc1 ; c1ccc(-c2ccc(-c3c4ccccc4c(-c4ccc(-n5c(-c6ccccc6)nc6ccccc65)cc4)c4ccccc34)cc2)cc1]

6. The organic light emitting diode of claim 1, wherein the first electron transport layer has a thickness different from a thickness of the second electron transport layer.

7. The organic light emitting diode of claim 1, wherein the emissive layer comprises:
a first emitting part disposed between the first electrode and the second electrode;
a second emitting part disposed between the first emitting part and the second electrode; and
a charge generation layer disposed between the first emitting part and the second emitting part, and
wherein the second emitting part comprises the at least one emitting material layer and the electron transport layer.

8. The organic light emitting diode of claim 7, wherein the at least one emitting material layer comprises:
a first layer disposed between the charge generation layer and the second electrode; and
a second layer disposed between the first layer and the second electrode.

9. The organic light emitting diode of claim 8, wherein the at least one emitting material layer further comprises a third layer disposed between the first layer and the second layer.

10. The organic light emitting diode of claim 1, wherein the emissive layer comprises:
a first emitting part disposed between the first electrode and the second electrode;
a second emitting part disposed between the first emitting part and the second electrode;
a third emitting part disposed between the second emitting part and the second electrode;
a first charge generation layer disposed between the first emitting part and the second emitting part; and
a second charge generation layer disposed between the second emitting part and the third emitting part, and
wherein the third emitting part comprises the at least one emitting material layer and the electron transport layer.

11. The organic light emitting diode of claim 1, wherein a thickness ratio of the first electron transport layer to the second electron transport layer is 1:1 to 1:10.

12. The organic light emitting diode of claim 1, wherein a thickness ratio of the first electron transport layer to the second electron transport layer is 1:1 to 10:1.

13. An organic light emitting diode comprising:
a first electrode;
a second electrode facing the first electrode; and
an emissive layer disposed between the first electrode and the second electrode, and comprising at least one emitting part,
wherein one of the at least one emitting part is disposed adjacently to the second electrode and comprises:
a blue emitting material layer; and
an electron transport layer disposed between the blue emitting material layer and the second electrode,
wherein the electron transport layer comprises:
a first electron transport layer disposed between the blue emitting material layer and the second electrode; and
a second electron transport layer disposed between the first electron transport layer and the second electrode,
wherein the first electron transport layer comprises a first electron transporting material having the following structure of Chemical Formula 1, and
wherein the second electron transport layer comprises a second electron transporting material having the following structure of Chemical Formula 4: 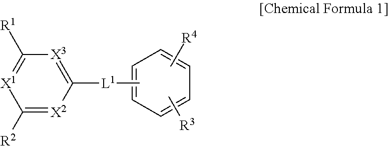
wherein, in Chemical Formula 1,
each of X¹ to X³ is independently CR⁵ or N, where at least two of X¹ to X³ is N;
each of R¹ to R⁵ is independently hydrogen, an unsubstituted or substituted C₁-C₂₀ alkyl group or an unsubstituted or substituted C₆-C₃₀ aryl group or an unsubstituted or substituted C₃-C₃₀ hetero aryl group, where at least one of R³ and R⁴ has an unsubstituted or substituted carbazolyl moiety; and
L¹ is a single bond, an unsubstituted or substituted C₆-C₃₀ arylene group or an unsubstituted or substituted C₃-C₃₀ hetero arylene group, 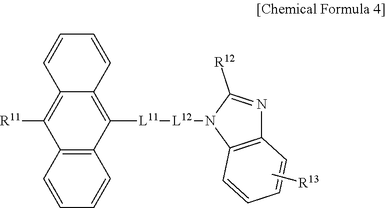
wherein, in Chemical Formula 4,
each of R¹¹ to R¹³ is independently hydrogen, an unsubstituted or substituted C₁-C₁₀ alkyl group, an unsubstituted or substituted C₆-C₃₀ aryl group or an unsubstituted or substituted C₃-C₃₀ hetero aryl group; and
each of L¹¹ and L¹² is independently a single bond, an unsubstituted or substituted C₆-C₃₀ arylene group or an unsubstituted or substituted C₃-C₃₀ hetero arylene group, where at least one of L¹¹ and L¹² is not a single bond.

14. The organic light emitting diode of claim 13, wherein the first electron transporting material has a structure of Chemical Formula 2: 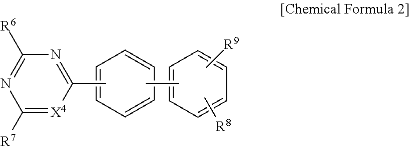
wherein, in Chemical Formula 2,
X⁴ is CR¹⁰ or N;
each of R⁶ and R⁷ is independently an unsubstituted or substituted C₆-C₃₀ aryl group;
each of R⁸ and R⁹ is independently an unsubstituted or substituted C₆-C₃₀ aryl group or an unsubstituted or substituted C₃-C₃₀ hetero aryl group, where at least one of R⁸ and R⁹ comprises an unsubstituted or substituted carbazolyl moiety; and
R¹⁰ is hydrogen or an unsubstituted or substituted C₁-C₂₀ alkyl group.

15. The organic light emitting diode of claim 13, wherein the second electron transporting material has a structure of Chemical Formula 5: 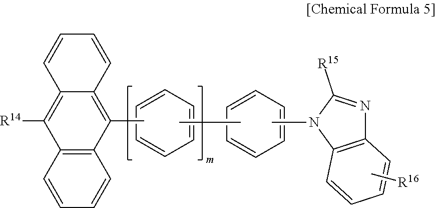
wherein, in Chemical Formula 5,
R¹⁴ is an unsubstituted or substituted C₆-C₃₀ aryl group;
R¹⁵ is hydrogen, an unsubstituted or substituted C₁-C₂₀ alkyl group or an unsubstituted or substituted C₆-C₃₀ aryl group;
R¹⁶ is hydrogen or an unsubstituted or substituted C₁-C₂₀ alkyl group; and
m is 0 or 1.

16. The organic light emitting diode of claim 13, wherein the first electron transport layer has a thickness different from a thickness of the second electron transport layer.

17. The organic light emitting diode of claim 13, wherein the emissive layer has a single emitting part.

18. The organic light emitting diode of claim 13, wherein the emissive layer comprises:
a first emitting part disposed between the first electrode and the second electrode;
a second emitting part disposed between the first emitting part and the second electrode;
a third emitting part disposed between the second emitting part and the second electrode;
a first charge generation layer disposed between the first emitting part and the second emitting part; and
a second charge generation layer disposed between the second emitting part and the third emitting part, and
wherein the third emitting part comprises the blue emitting material layer and the electron transport layer.

19. The organic light emitting diode of claim 13, wherein the second emitting part comprises at least one emitting material layer,
wherein the at least one emitting material layer comprises:
a first layer disposed between the first charge generation layer and the second electrode; and
a second layer disposed between the first layer and the second electrode, and
wherein one of the first layer and the second layer is a red emitting material layer and another of the first layer and the second layer is a green emitting material layer.

20. The organic light emitting diode of claim 19, wherein the at least one emitting material layer further comprises a third layer of a yellow-green emitting material layer disposed between the first layer and the second layer.

21. The organic light emitting diode of claim 13, wherein a thickness ratio of the first electron transport layer to the second electron transport layer is 1:1 to 1:10.

22. The organic light emitting diode of claim 13, wherein a thickness ratio of the first electron transport layer to the second electron transport layer is 1:1 to 10:1.

23. An organic light emitting diode comprising:
a first electrode;
a second electrode; and
an emissive layer disposed between the first electrode and the second electrode, and comprising at least one emitting part,
wherein one of the at least one emitting part is disposed adjacently to the second electrode and comprises:
at least one emitting material layer; and
an electron transport layer disposed between the at least one emitting material layer and the second electrode,
wherein the electron transport layer comprises:
a first electron transport layer disposed between the at least one emitting material layer and the second electrode; and
a second electron transport layer disposed between the first electron transport layer and the second electrode,
wherein the first electron transport layer comprises a first electron transporting material having the following structure of Chemical Formula 2, and
wherein the second electron transport layer comprises a second electron transporting material having the following structure of Chemical Formula 5: 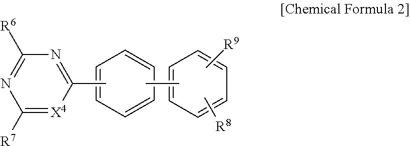
wherein, in Chemical Formula 2,
X⁴ is CR¹⁰ or N;
each of R⁶ and R⁷ is independently an unsubstituted or substituted C₆-C₃₀ aryl group;
each of R⁸ and R⁹ is independently an unsubstituted or substituted C₆-C₃₀ aryl group or an unsubstituted or substituted C₃-C₃₀ hetero aryl group, where at least one of R⁸ and R⁹ comprises an unsubstituted or substituted carbazolyl moiety; and
R¹⁰ is hydrogen or an unsubstituted or substituted C₁-C₂₀ alkyl group; 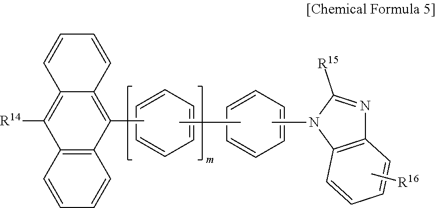
wherein, in Chemical Formula 5,
R¹⁴ is an unsubstituted or substituted C₆-C₃₀ aryl group;
R¹⁵ is hydrogen, an unsubstituted or substituted C₁-C₂₀ alkyl group or an unsubstituted or substituted C₆-C₃₀ aryl group;
R¹⁶ is hydrogen or an unsubstituted or substituted C₁-C₂₀ alkyl group; and
m is 0 or 1.

24. The organic light emitting diode of claim 23, wherein the first electron transporting material is at least one of the following organic compounds: 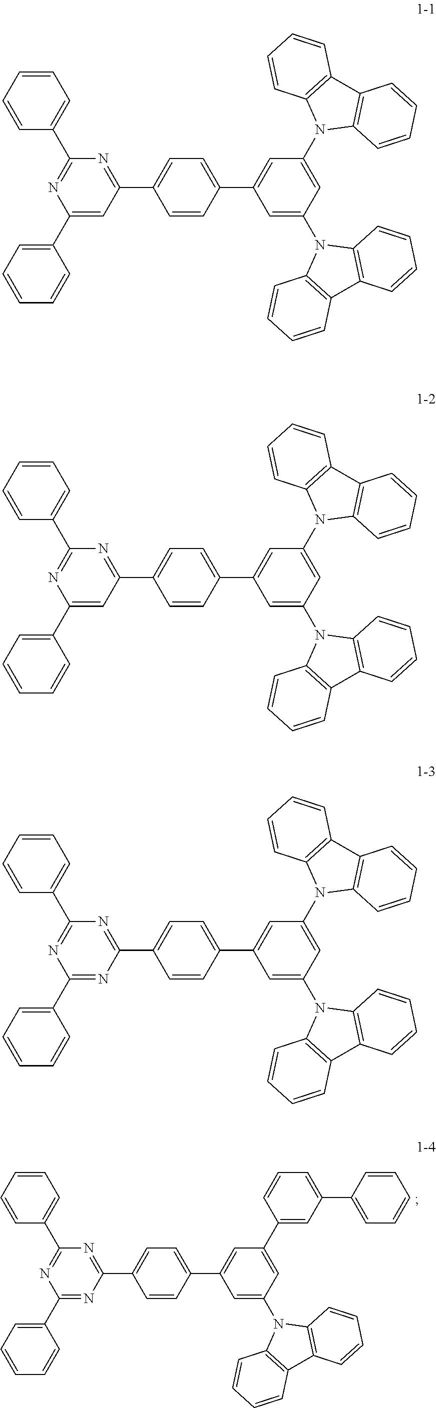 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)cc3)n2)cc1 ; c1ccc(-c2cccc(-c3cc(-c4ccc(-c5nc(-c6ccccc6)nc(-c6ccccc6)n5)cc4)cc(-n4c5ccccc5c5ccccc54)c3)c2)cc1]
and
wherein the second electron transporting material is at least one of the following compounds:

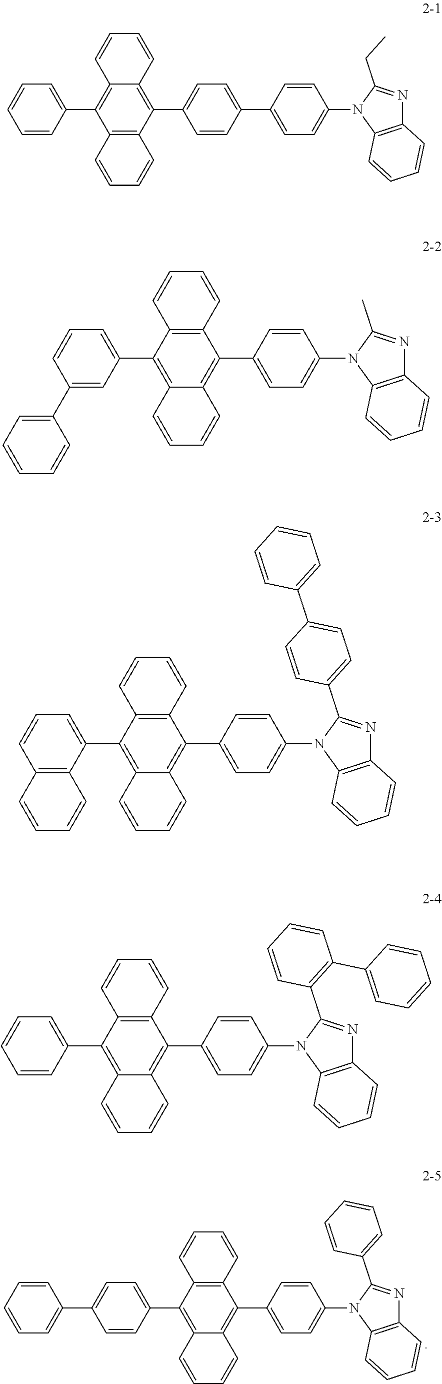 [SMILES: CCc1nc2ccccc2n1-c1ccc(-c2ccc(-c3c4ccccc4c(-c4ccccc4)c4ccccc34)cc2)cc1 ; Cc1nc2ccccc2n1-c1ccc(-c2c3ccccc3c(-c3cccc(-c4ccccc4)c3)c3ccccc23)cc1 ; c1ccc(-c2ccc(-c3nc4ccccc4n3-c3ccc(-c4c5ccccc5c(-c5cccc6ccccc56)c5ccccc45)cc3)cc2)cc1 ; c1ccc(-c2ccccc2-c2nc3ccccc3n2-c2ccc(-c3c4ccccc4c(-c4ccccc4)c4ccccc34)cc2)cc1 ; c1ccc(-c2ccc(-c3c4ccccc4c(-c4ccc(-n5c(-c6ccccc6)nc6ccccc65)cc4)c4ccccc34)cc2)cc1]

25. An organic light emitting device, comprising:
a substrate; and
the organic light emitting diode of claim 19 over the substrate.
